(19) United States
(12) Patent Application Publication
(10) Pub. No.: US 2015/0136233 A1
(43) Pub. Date: May 21, 2015

(54) ORGANIC PHOTOVOLTAIC DEVICES COMPRISING FULLERENES AND DERIVATIVES

(71) Applicant: The Regents of the University of California, Oakland, CA (US)

(72) Inventors: Hengbin Wang, Santa Barbara, CA (US); Johannes Sprafke, Ludwigshafen (DE); Laura Neumann, Eindhoven (NL); Craig J. Hawker, Santa Barbara, CA (US); Ming Wang, Beijing (CN)

(73) Assignee: THE REGENTS OF THE UNIVERSITY OF CALIFORNIA, Oakland, CA (US)

(21) Appl. No.: 14/546,282

(22) Filed: Nov. 18, 2014

Related U.S. Application Data
(60) Provisional application No. 61/905,747, filed on Nov. 18, 2013.

(51) Int. Cl. H01L 51/00

(52) U.S. Cl. CPC H01L 51/0047; H01L 51/0002; H01L 51/424
USPC 136/263; 252/500

(57) ABSTRACT

The instant application teaches methods, compositions and devices useful in forming an active layer in photovoltaic cell devices. In typical embodiments of the invention, the active layer in photovoltaic cell devices is formed by selecting and combining certain constellations of complimentary donor and acceptor compounds.

### REFERENCE TO RELATED APPLICATIONS

This application claims the benefit under 35 U.S.C. Section 119(e) of co-pending U.S. Provisional Patent Application Ser. No. 61/905,747, filed on Nov. 18, 2013, entitled “ORGANIC PHOTOVOLTAIC DEVICES COMPRISING FULLERENES AND DERIVATIVES”, the contents of which are incorporated herein by reference.

### TECHNICAL FIELD

This invention relates generally to fullerene derivatives, and in particular, organic photovoltaic (OPV) devices (also known as organic solar cells) comprising fullerene derivatives.

### BACKGROUND OF THE INVENTION

Organic solar cell efficiency has reached 10% recently mainly due to the advance of new low bandgap donor materials. There are far fewer high performance acceptor materials available and PCBM (both PC₆₁BM, phenyl-C₆₁-butyric acid methyl ester and PC₇₁BM, phenyl-C₇₁-butyric acid methyl ester) is still the most widely used acceptor materials [1-12]. A major effort on acceptor development has been focused on acceptors with a lowest unoccupied molecular orbital (LUMO) higher than that of PCBM, such as bis-PCBM and ICBA, to achieve a higher device open circuit voltage [13-20]. Much less attention has been paid to new acceptors with LUMO levels lower than or similar to that of PCBM.

In the development of practical organic solar cells, it has been realized that both device efficiency and stability are equally important. To keep the device from oxidative degradation, it is necessary to have the highest occupied molecular orbital (HOMO) of the semiconducting donor material lower than the oxygen oxidation threshold of −5.27 eV (0.57 V vs. SCE) [21]. On the other hand, to maximize light absorption, the bandgap of the donor needs to be narrow, preferably narrower than 1.5 eV [22]. This leads to an optimized LUMO level of the donor that is lower than −3.7 eV, which is less than 0.1 eV higher than the LUMO of PCBM [23-24]. As illustrated in FIG. 1, the general consensus is that the donor/acceptor LUMO band offset needs to be at least 0.3 eV for efficient charge separation[22]. In this case, the charge separation from donors to fullerene acceptors such as PCBM or ICBA may be inefficient, which leads to decreased device efficiency. To overcome this issue, fullerenes with LUMO lower than that of PCBM need to be developed.

Furthermore, small and crystalline molecules such as C₆₀, C₇₀ and PCBM or ICMA tend to diffuse and aggregate into larger clusters or crystals in the bulk heterojunction layer of a solar cell during continuous thermal annealing, or high temperature operation, which results in a deterioration in performance of the device as well as a decreased lifespan for the organic solar cell [35]. Some studies have found that multi-functionalized fullerenes which contain a mixture of regioisomers, such as bis-PCBM, ICBA, di(4-methylphenyl)methano-C60 bis-adduct (DMPCBA), and dihydronaphthyl-based [60]fullerene, have an amorphous nature in solids and may improve bulk heterojunction thermal stability [36, 37]. However, such studies still mainly focus on obtaining high-LUMO multi-functionalized fullerenes. Thus, there is a need for low-LUMO multi-functionalized fullerenes that achieve both good device efficiency and stability [38].

### SUMMARY OF THE INVENTION

The invention disclosed herein includes new compositions useful for forming active layers in photovoltaic cell devices. Embodiments of the invention include methods and materials for forming photovoltaic cell devices, as well as devices made by these methods. As discussed in detail below, typical embodiments of the invention include devices designed to include an active layer formed by combining compositions selected to have certain constellations of complimentary donor and acceptor compounds.

Illustrative embodiments of the invention include photovoltaic cell devices having an active layer comprising at least one of an electron donor and an electron acceptor comprising a fullerene. In one or more embodiments, the electron donor is selected to have a LUMO level not more than 0.4 eV higher than the LUMO level of [6,6]-phenyl-C₆₁-butyric acid methyl ester (PCBM) or bis(1-[3-(methoxycarbonyl)propyl]-1-phenyl)[6,6]C₆₂ (bis-PCBM) and the electron acceptor comprises a fullerene having a LUMO energy level lower than that of PCBM or bis-PCBM. Certain devices include an active layer comprising an electron donor selected to have a LUMO level not more than 0.4 eV higher than the LUMO level of PCBM in combination with an electron acceptor having a LUMO energy level lower than that of PCBM. Other devices include an active layer comprising an electron donor selected to have a LUMO level not more than 0.4 eV higher than the LUMO level of bis-PCBM in combination with an electron acceptor having a LUMO energy level lower than that of bis-PCBM. Yet another embodiment of the invention is a photovoltaic cell device with an active layer comprising at least one of an electron donor selected to have a LUMO level not less than 0.1 eV lower than the LUMO level of regioregular poly(3-hexylthiophene) (rr-P3HT) and an electron acceptor comprising a fullerene selected to have a LUMO energy level lower than that of PCBM or bis-PCBM.

Embodiments of the invention also include a plurality of the photovoltaic cells disclosed herein, wherein at least some of the photovoltaic cells are electrically connected. Typically, the device exhibits a power conversion efficiency higher than a power conversion efficiency of a control device with PCBM as an electron acceptor. In certain embodiments, the photovoltaic cell exhibits an efficiency of at least about 1.0%. In other embodiments, thermally annealing the active layer at 160° C. for one hour results in a power conversion efficiency of at least 60% of the original power conversion efficiency of the active layer. In still other embodiments, thermally annealing the active layer at 160° C. for one hour results in a device with a power conversion efficiency that is higher than a control device that utilizes PCBM as an electron acceptor. In further embodiments, thermally annealing the active layer at 160° C. for one hour results in a device with a power conversion efficiency that is at least 2 times higher than a control device that utilizes PCBM as an electron acceptor. In other embodiments, the loading of the fullerene is from 0.1 weight percent (wt %) to 99 wt % solubility in a solvent used to form the active layer (i.e. fullerene to solvent ratio).

The donor materials used in the photovoltaic devices can be selected from various semiconducting small molecules, oligomers, dendrimers, polymers or copolymers.

Embodiments of the invention use selected donor and acceptor compounds. For example, in certain embodiments of the invention, the electron acceptor comprises a pristine fullerene. In other embodiments of the invention, the electron acceptor comprises a mono-, bis- or tris-fullerene. In still further embodiments of the invention, the electron acceptor comprises a functionalized fullerene or fullerene derivative having the formula:

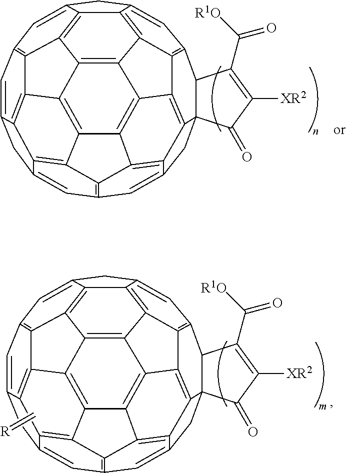

wherein the fullerene core exhibits the formula C₂ₙ, such as C₆₀, C₇₀ or C₈₄. X is selected from the group consisting of nitrogen, oxygen and sulfur. R¹ and R² are independently selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; a carbonyl, carboxylate, nitro, sulfonyl, amino, amide, cyano, hydroxyl, thiol, silyl, siloxy or halogen group (including combinations of said R¹ and R² groups); and m is equal to 1 or 2 and n is equal to 1, 2 or 3. In these fullerene compounds, the R group comprises one or two optionally substituted organic groups which are covalently bonded to the surface of the fullerene core by two single covalent bonds [20]. The two bonds can be between the R group(s) and two carbons adjacent to each other on the fullerene surface, or can be between the R group(s) and two carbons in the same six or five membered rings on the fullerene surface, or can be between the R group(s) and two carbons in difference six or five membered rings on the fullerene surface. The two bonds can be between two carbon atoms on the fullerene surface and a same carbon or heteroatom on one R group, or between two carbon atoms on the fullerene surface and two difference carbons or heteroatoms on one R group, or between two carbon atoms on the fullerene surface and two different carbon or heteroatoms on two R groups respectively.

In one or more embodiments, the electron acceptor comprises at least 2 covalent bonds between the fullerene core and R. In certain embodiments, the at least 2 covalent bonds are bound to different carbons in the fullerene core. In other embodiments, the at least 2 covalent bonds are bound to 1,2-carbons or 1,4-carbons of a six-member ring in the fullerene core. The fullerene derivatives with the R groups can be methanofullerene derivatives, PCBM derivatives, Prato derivatives, Bingel derivatives, fulleropyrrolidines, diazoline derivatives, azafulleroid derivatives, Diels-Alder derivatives, indene fullerenes, dihydronaphthyl derivatives, 1,4-di(organo)fullerenes [20, 43-49]; R can be selected from, but not limited to, the following functional groups:

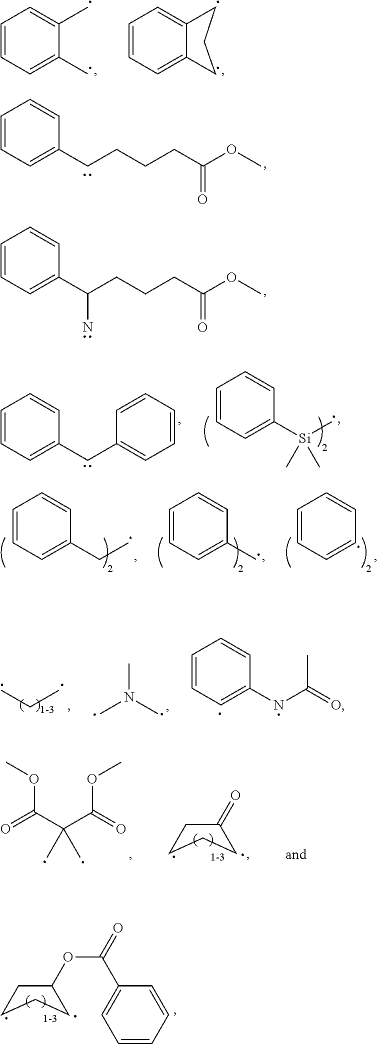

where the two dots on each functional group indicate the two bonding positions to the fullerene core.

In certain instances, the fullerene has the formula:

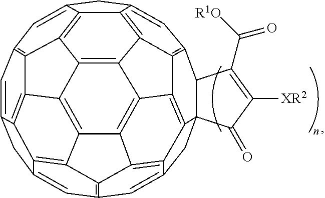

wherein C₆₀, R¹=Me, R²=Ph, X═O, n=1; C₆₀, R¹=Me, R²=Ph, X═O, n=2; C₆₀, R¹=Me, R²=Me, X═O, n=1; C₆₀, R¹=Me, R²=Me, X═O, n=2; C₆₀, R¹=Me, R²═F₂Ph, X═O, n=1; C₆₀, R¹=Me, R²═F₂Ph, X═O, n=2; C₆₀, R¹=Me, R²═F₅Ph, X═O, n=1; C₆₀, R¹=Me, R²═F₅Ph, X═O, n=2; C₆₀, R¹=Me, R²=Ph, X═S, n=1; C₆₀, R¹=n-Bu, R²=Ph, X═O, n=1; C₆₀, R¹=n-Bu, R²=Ph, X═O, n=2; C₆₀, R¹=n-Bu, R²=n-Bu, X═O, n=1; C₆₀, R¹=n-Bu, R²=n-Bu, X═O, n=2; C₇₀, R¹=n-Bu, R²=Ph, X═O, n=1; or C₇₀, R¹=n-Bu, R²=Ph, X═O, n=2. In other instances, the fullerene has the formula:

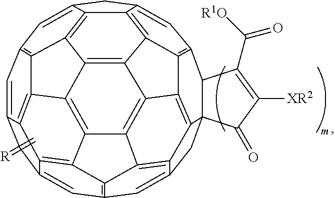

wherein R═

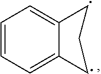

### R¹═R²=Me or R═

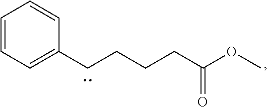

R¹═R²=Me, m is equal to 1 or 2

In further illustrative embodiments, an active layer may be formed between electrodes in an organic photovoltaic cell so that it comprises a mixture of a first fullerene and a second fullerene different from the first fullerene. Optionally, the first fullerene comprises at least 50%, 60%, 70%, 80%, 90%, 95%, 99%, or 99.5% of the mixture by weight. As noted above, the electron acceptor is selected to comprise a pristine fullerene, a functionalized fullerene having a formula noted herein, a compound disclosed herein, as well as mixtures of the compounds, for example a mixture of mono-fullerenes and bis-fullerenes. In one or more embodiments, the mixture of different fullerenes comprises at least two compounds selected to have LUMO levels within 0.05 eV of each other. In further embodiments, the organic photovoltaic cell exhibits a power conversion efficiency higher than a power conversion efficiency of a substantially analogous control device with PCBM as an electron acceptor.

Embodiments of the invention also include methods of forming the devices disclosed herein. The method comprises forming an active layer composition including an electron donor and an electron acceptor. In one such embodiment, the electron donor is selected to exhibit a LUMO level not more than 0.40 eV, 0.35 eV, 0.30 eV, 0.25 eV, 0.2 eV, 0.15 eV, 0.1 eV or 0.05 eV higher than the LUMO level of PCBM. In certain embodiments, the electron donor has a LUMO level at least 0.1 eV, 0.2 eV, 0.3 eV, 0.4 eV or 0.5 eV lower than the LUMO level of regioregular poly(3-hexylthiophene) (rr-P3HT). The electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than that of PCBM. In another embodiment, the electron acceptor comprises at least one bis-fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of bis-PCBM.

Yet another embodiment of the invention is a method of forming an organic photovoltaic cell by forming an active layer composition including an electron donor and an electron acceptor. The electron donor is selected to exhibit a LUMO level not less than 0.1 eV lower than the LUMO level of regioregular poly(3-hexylthiophene) (rr-P3HT) and/or the electron acceptor comprises a fullerene selected to exhibit a LUMO energy level lower than that of PCBM or bis-PCBM. Typically, the active layer comprises an electron donor selected to exhibit a LUMO level not less than 0.1 eV lower than the LUMO level of regioregular poly(3-hexylthiophene) (rr-P3HT) in combination with a fullerene selected to exhibit a LUMO energy level lower than that of PCBM or bis-PCBM.

Methodological embodiments of the invention include those where the electron donor and the electron acceptor are selected to exhibit compatible solubility profiles. For example, in some embodiments of the invention the electron donor and the electron acceptor are selected to exhibit compatible solubility profiles such that a single solvent is used for forming the active layer on a surface of the device. In some embodiments of the invention, the electron donor and the electron acceptor are selected to exhibit compatible solubility profiles such that each exhibit an at least 0.5 weight percent (wt %) solubility in a solvent used to form the active layer. Optionally, the electron donor compound and the electron acceptor compound are selected to exhibit compatible solubility profiles such that each exhibit an at least 1, 2, 3, 4, 5, 6, 7, or 8 wt % solubility in a solvent used to form the active layer. See, e.g. FIG. 6 which shows the solubility in chloroform of various fullerenes disclosed herein. In illustrative embodiments, the solvent comprises at least one of the group selected from chlorobenzene, 1,2-dichlorobenzene, chloroform, toluene, xylene, ethyl benzoate, and tetralin.

Other objects, features and advantages of the present invention will become apparent to those skilled in the art from the following detailed description. It is to be understood, however, that the detailed description and specific examples, while indicating some embodiments of the present invention are given by way of illustration and not limitation. Many changes and modifications within the scope of the present invention may be made without departing from the spirit thereof, and the invention includes all such modifications.

### BRIEF DESCRIPTION OF THE DRAWINGS

FIG. 1 is a schematic illustration of inefficient charge separation in stable organic solar cells with PCBM as the acceptor.

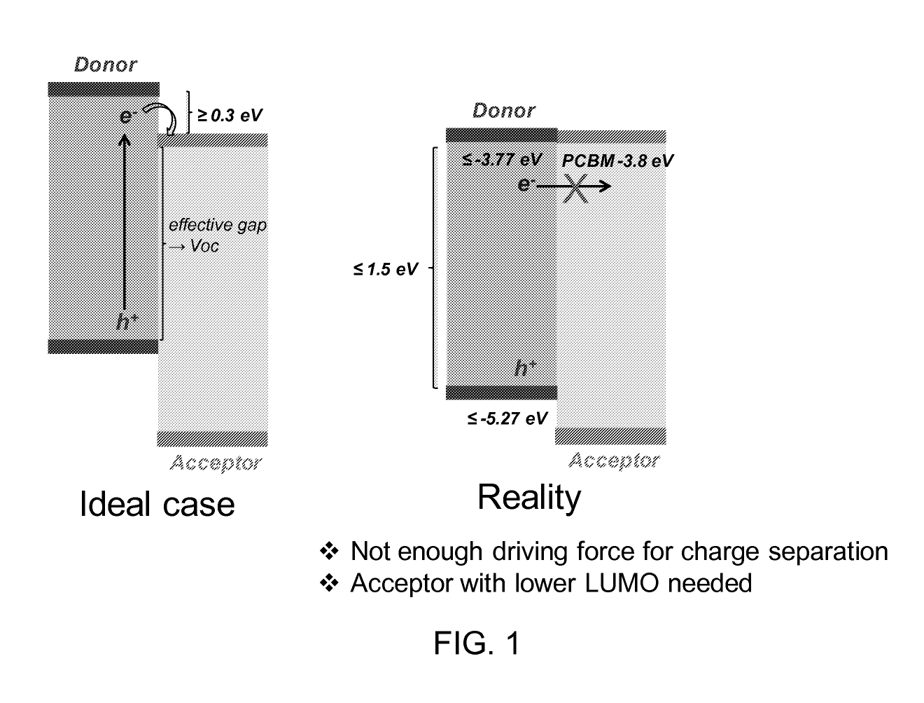

FIG. 2 illustrates Thermo gravimetric analysis profiles of fullerene derivatives C60CP-PhMe1 and C60CP-F5PhMe1.

FIG. 3 illustrates EQE profiles of devices as listed herein in Table 3.

FIG. 4 illustrates UV-vis. Absorption spectra of devices as listed herein in Table 3.

FIG. 5 is a cross sectional schematic of a bulk heterojunction solar cell having an active region including the polymer or small molecule, according to one or more embodiments of the invention.

FIG. 6 shows the solubility of various fullerenes in chloroform, according to one or more embodiments of the invention.

FIG. 7 is a graph illustrating the absence of side products of one or more embodiments of the invention.

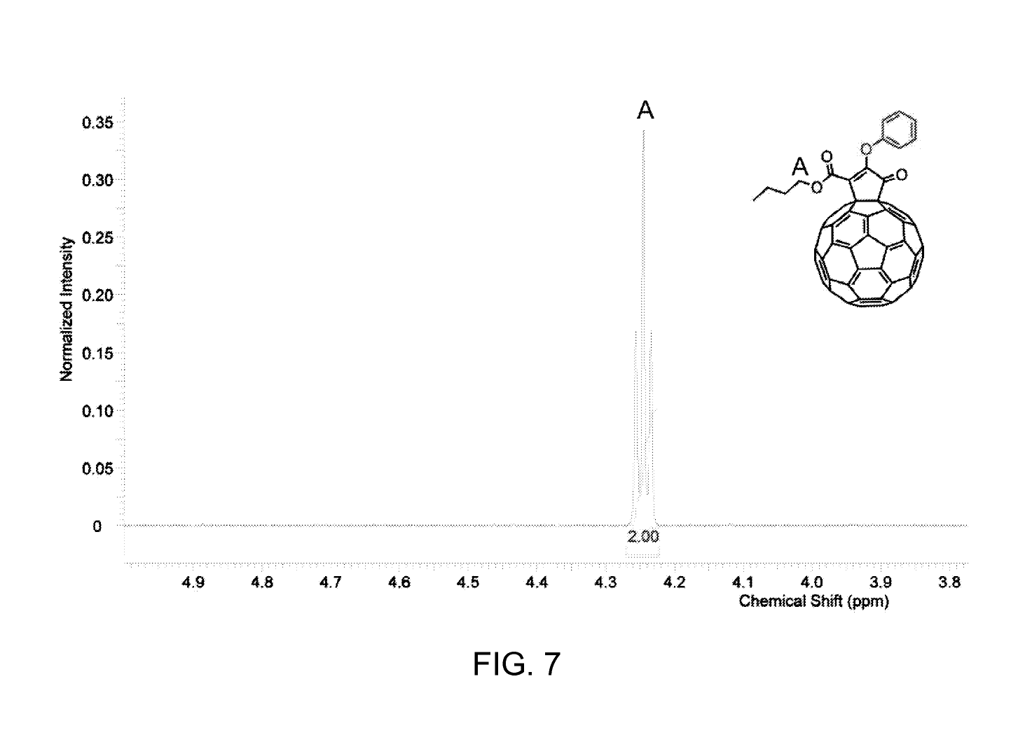

FIG. 8 is a graph illustrating the unique LUMO levels of various mono- and bis-fullerenes disclosed herein, according to one or more embodiments of the invention.

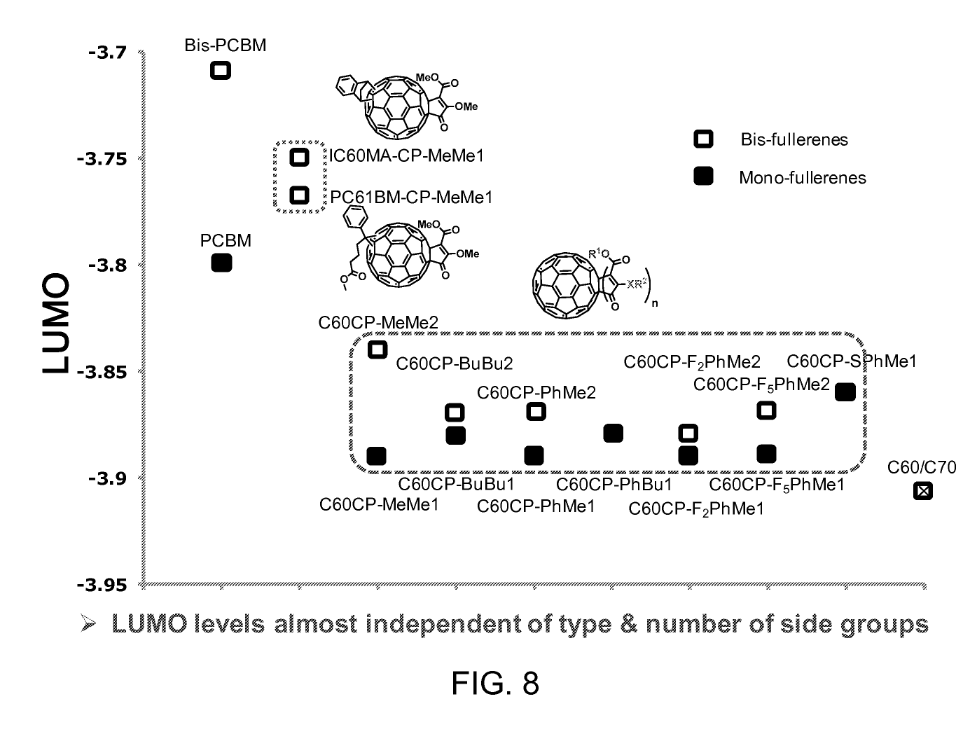

FIG. 9 is a graph illustrating PCE vs. annealing time of various fullerenes based devices.

FIG. 10 shows optical images of various fullerene based devices after annealing at 160° C. for an hour.

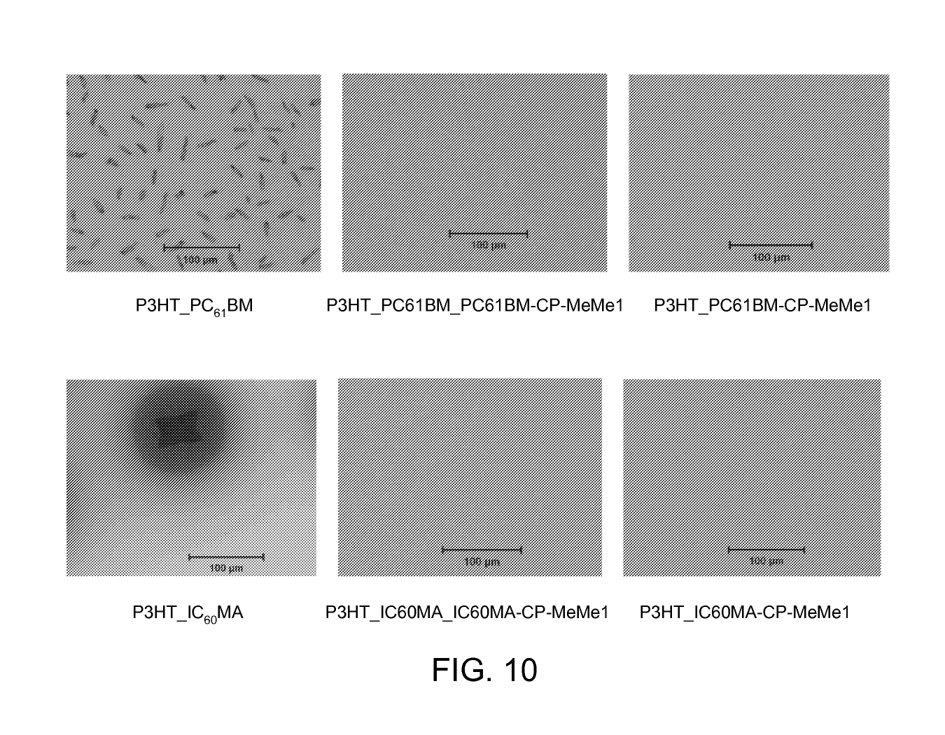

FIG. 11 illustrates the better performance (greater charge separation) obtained with various low LUMO polymer donors disclosed herein, according to one or more embodiments of the invention.

### DETAILED DESCRIPTION OF THE INVENTION

Unless otherwise defined, all terms of art, notations and other scientific terms or terminology used herein are intended to have the meanings commonly understood by those of skill in the art to which this invention pertains. Many of the techniques and procedures described or referenced herein are well understood and commonly employed using conventional methodology by those skilled in the art. It is to be understood that other embodiments may be utilized and structural changes may be made without departing from the scope of the present invention.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, in the context of organic materials, the terms “donor” and “acceptor” refer to the relative positions of the HOMO and LUMO energy levels of two contacting but different organic materials. This is in contrast to the use of these terms in the inorganic context, where “donor” and “acceptor” may refer to types of dopants that may be used to create inorganic n- and p-types layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, the term “fullerene” means any fullerene or a derivative thereof. Fullerenes include C₂₀ to C₁₀₀, in particular C₆₀, C₇₀, and C₈₄ and their mixtures thereof. For example, the electron acceptor material can include a substituted fullerene or fullerene derivative, such as [6,6]-phenyl C₆₁-butyric acid methyl ester (PCBM or PC₆₁BM), [6,6]-phenyl C₇₁-butyric acid methyl ester (PC₇₁BM), bis(1-[3-(methoxycarbonyl)propyl]-1-phenyl)[6.6]C₆₂ (bis-PCBM or bis-PC₆₁BM), 3′Phenyl-3′H-cyclopropa[8,25][5,6]fullerene-C₇₀-bis-D5h(6)-3′ butanoic acid methyl ester (bis-PC₇₁BM), and 1′,4′-dihydro-naphtho[2′,3′:1,2][5,6]fullerene-C₆₀ (ICMA). The term “fullerene core” or “fullerene cage” represents the pristine fullerene part of the fullerene derivative. A pristine fullerene refers to a fullerene molecule without any functional groups attached to it, e.g. C₆₀, C₇₀, and C₈₄. A mono-, bis-, and tris-fullerene represent a fullerene molecule with one, two, and three functional groups attached to it respectively.

As used herein, the term “heteroaryl” represents a monocyclic- or polycyclic aromatic ring comprising carbon atoms, hydrogen atoms, and one or more heteroatoms, independently selected from nitrogen, oxygen, sulfur, silicon, boron, phosphous, germanium. Illustrative examples of heteroaryl groups include, but are not limited to, azaborininyl, azaphosphininyl, borolyl, furanyl, germolyl, imidazolyl, indolyl, isoindolyl, isoquinolinyl, isoxazolyl, oxazolyl, phenanthridinyl, pyridinyl, pyridazinyl, pyrimidyl, pyrazyl, pyrrolyl, pyrazolyl, quinolinyl, silolyl, thienyl, triazinyl, triazolyl, pyrazinyl, pyrimidinyl, tetrazolyl, and thiazolyl. The term “fluoroaryl” represents a monocyclic- or polycyclic aromatic ring comprising of one or more fluoride substituents.

Certain aspects of the invention disclosed herein are characterized by comparisons to a control device having a substantially analogous structure. As is generally understood by one skilled in the art, a control device is a device that can be used as a standard of comparison for testing the relative impact of certain variables or elements (e.g. compositions used to form an electron donor or acceptor within a photovoltaic cell device). For example, in one or more embodiments, a photovoltaic cell device formed with an electron acceptor composition as disclosed herein, is shown to exhibit a power conversion efficiency higher than a power conversion efficiency of a control device which instead uses a PCBM composition as an electron acceptor. In such contexts, the photovoltaic cell device having an electron acceptor composition as disclosed herein is properly described as exhibiting a power conversion efficiency higher than a power conversion efficiency of an identical or substantially analogous device (e.g. one with an essentially identical structure) but which substitutes a PCBM composition as an electron acceptor.

As noted above, embodiments of the invention include methods and materials for forming photovoltaic cell devices, as well as devices made by these methods. As discussed in detail below, typical embodiments of the invention include devices designed to include an active layer formed by combining compositions selected to have certain constellations of complimentary donor and acceptor compounds.

Aspects of the instant disclosure provide evidence that the fullerene compounds and mixtures disclosed herein have great commercial value as an electron acceptor for organic or hybrid solar cells. For example as shown below, they can be readily synthesized and purified by a one pot reaction with excellent yield. In addition, as described in further detail below, their solubility can be readily tuned by changing the R¹ and R² groups. They may exhibit an LUMO energy level lower than that of PCBM, which makes them a better candidate to combine with narrow bandgap, low LUMO donor materials. Furthermore, variation of the type (X, R¹ and R² group) and the number of functional groups has little effect on the LUMO energy levels of these fullerenes, which makes it possible to achieve excellent solar cell device efficiency with low cost, mixed fullerenes. See also, e.g. [39-42]. Some of the bis and tris fullerenes may exhibit a LUMO energy level lower than bis-PCBM and close to PCBM, which makes them a good candidate as PCBM replacement or additive and renders better device thermal stability.

A typical universal precursor strategy is as follows [26]:

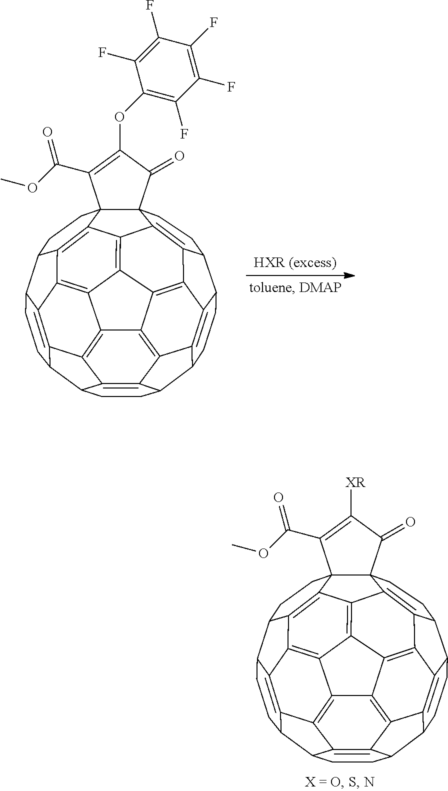

However, an issue with the universal precursor strategy is that, as found in an illustrative experiment, 300 equivalent (eq) of HXR (where X═O, S, N) works but 20 eq does not. There is also an issue with the presence of precipitation. Thus, in one aspect of the present invention, a highly efficient, zwitterion-mediated approach is provided for the modular functionalization of fullerenes. This approach allows for the introduction of a variety of functional groups on the fullerenes in a one-pot reaction sequence. The resulting fullerene derivatives are highly interesting for solar cell and other applications. However, there have been no reports on the properties of these types of fullerenes thus far. The fullerene derivatives (I) as described herein may, in one instance, be synthesized following this approach (Scheme 1).

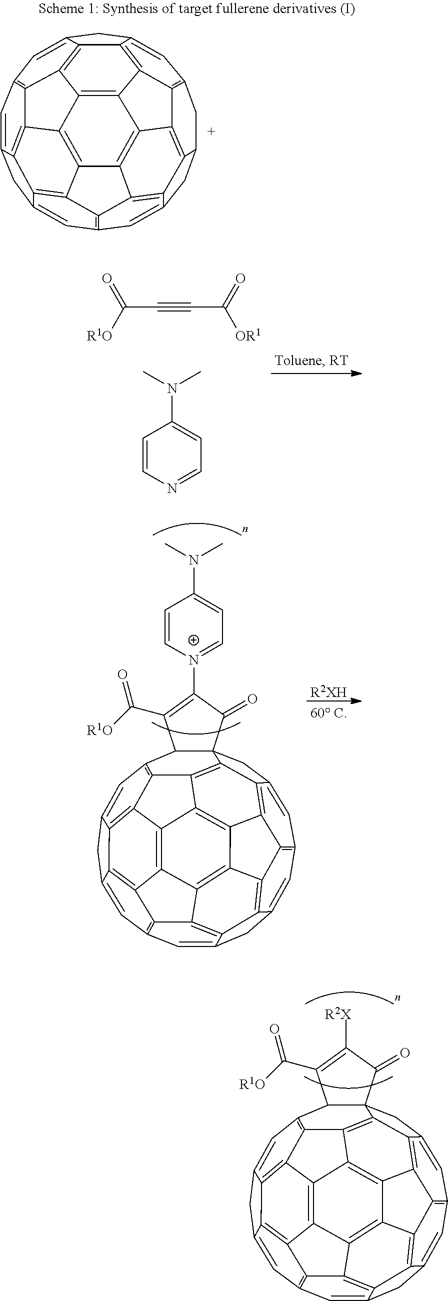

Embodiments of the invention include solar cell devices comprising an active layer comprising an electron donor with a LUMO level no higher than about 0.4 eV to about 0.05 eV of the LUMO level of PCBM and one or more fullerenes as an electron acceptor. The fullerenes can be a pristine fullerene or functionalized fullerene derivatives incorporating a five membered cyclopentene ring as shown in the structure (I) below.

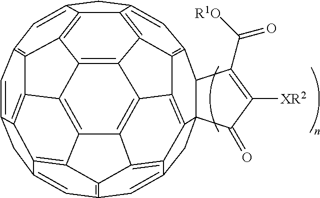

Fullerene (I), X═O, S, N; n=1, 2, 3

In various embodiments, the fullerene core has the formula of C₂ₙ as C₆₀, C₇₀, C₈₄; n equal to 1 to 3, X equal to O, S, N; R′, R², can independently equal to hydrogen, alkyl, alkenyl or alkynyl with Cₙ (n=1 to 30), aryl with Cₙ (n=4 to 30), heteroaryl with Cₙ (n=2 to 30), fluoroalkyl with Cₙ (n=1 to 30), fluoroaryl with Cₙ (n=2 to 30), —(CH₂CH₂O)ₙ (n=1˜20), carbonyl, carboxylate, nitro, sulfonyl, amino, amide, cyano, hydroxyl, thiol, silyl, siloxy, halogen, any combination thereof, or any other chemical moieties which can be suitably bonded to the X group.

The fullerene derivatives (I) exhibit readily tunable solubility and a LUMO energy level lower than that of PCBM, which makes them a better candidate when combining with narrow bandgap, low LUMO donor materials. Furthermore, variation of the type (X, R¹ and R² groups) and number of functional groups has little effect on the LUMO energy levels of these fullerene derivatives, which makes it possible to achieve excellent solar cell device efficiency with mixed fullerenes.

Other than pristine fullerenes C₆₀, C₇₀ and C₈₄, fullerene derivatives such as PCBM and ICMA can be functionalized by this zwitterion-mediated approach too. The fullerene derivatives (II) as described herein may, in one instance, be synthesized following this approach (Scheme 2).

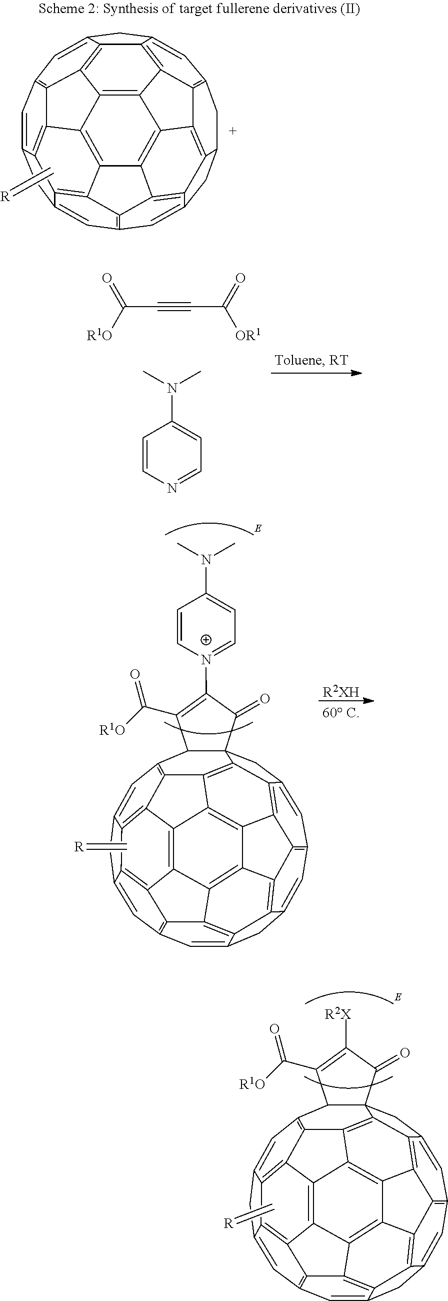

The fullerene derivatives (II) exhibit readily tunable solubility and an LUMO energy level lower than that of bis-PCBM, which makes them a good candidate when combining with narrow bandgap, low LUMO donor materials. The fullerene derivatives (II) may exhibit a LUMO energy level lower than bis-PCBM and close to PCBM, which makes it possible to achieve excellent solar cell device efficiency with mixed fullerenes and better device thermal stability.

In various embodiments of the invention, the electron acceptor further comprises a mixture of different fullerenes, for example a mixture of different fullerenes comprising a compound having a five membered cyclopentene ring as shown in Schemes 1-2 above and/or a compound disclosed in the Figures and/or a compound shown in Tables 1-6 below and/or a mono-fullerene and/or a bis-fullerene and/or a tris fullerene and/or a pristine fullerene. In an illustrative embodiment of the invention, the device comprises a first electrode, a second electrode, and active layer disposed between the first and second electrodes, wherein the active layer comprises a combination of different fullerene compounds, for example, a mono-fullerene and a bis-fullerene. In one or more embodiments, the mixture of different fullerenes comprises at least two compounds selected to have LUMO levels within 0.05 eV of each other.

A series of mono and bis-fullerenes are provided that have unique LUMO energy levels. They work well as the acceptor of organic solar cells, especially combining with low LUMO donors. Mixtures of mono and bis-fullerenes can be used as well due to their close LUMO levels. As described in the Example section below, illustrative bis-fullerenes have been synthesized and tested. Some of them have mixed functional groups and LUMO levels close to PCBM and lower than bis-PCBM. They may be used as additives to increase polymer solar cell thermal stability.

In one aspect of the invention, a photovoltaic cell device is provided. The photovoltaic cell device includes an active layer comprising at least one of an electron donor and an electron acceptor comprising a fullerene. The electron acceptor is selected to have a LUMO energy level lower than that of [6,6]-phenyl-C₆₁-butyric acid methyl ester (PCBM) or bis(1-[3-(methoxycarbonyl)propyl]-1-phenyl)[6,6]C₆₂ (bis-PCBM).

In one or more embodiments, the photovoltaic cell device includes an active layer comprising at least one of an electron donor selected to exhibit a LUMO level not more than 0.4 eV higher than the LUMO level of [6,6]-phenyl-C₆₁-butyric acid methyl ester (PCBM) and an electron acceptor comprising a fullerene. Specifically, the electron donor may be selected to have a LUMO level not more than 0.3 eV, 0.2 eV, or 0.1 eV higher than the LUMO level of PCBM. In one example, the active layer comprises an electron donor selected to have a LUMO level not more than 0.4 eV higher than the LUMO level of PCBM in combination with an electron acceptor selected to have a LUMO energy level lower than that of PCBM. Furthermore, the electron acceptor may be selected to have a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of PCBM.

In other embodiments, the photovoltaic cell device includes an active layer comprising at least one of an electron donor selected to exhibit a LUMO level not more than 0.4 eV higher than the LUMO level of bis(1-[3-(methoxycarbonyl)propyl]-1-phenyl)[6,6]C₆₂ (bis-PCBM) and an electron acceptor comprising a bis-fullerene. The electron acceptor is selected to have a LUMO energy level lower than that of bis-PCBM. Specifically, the electron donor may be selected to have a LUMO level not more than 0.3 eV, 0.2 eV, or 0.1 eV higher than the LUMO level of bis-PCBM. Furthermore, the electron acceptor may be selected to have a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of bis-PCBM.

In one or more embodiments, the photovoltaic cell comprises at least one of an electron donor selected to have a LUMO level not less than 0.1 eV lower than the LUMO level of regioregular poly(3-hexylthiophene) (rr-P3HT) and an electron acceptor comprising a fullerene. In certain embodiments, the electron donor has a LUMO level at least 0.1 eV, 0.2 eV, 0.3 eV, 0.4 eV or 0.5 eV lower than the LUMO level of regioregular poly(3-hexylthiophene) (rr-P3HT). In certain embodiments the electron acceptor is selected to have a LUMO energy level lower than that of [6,6]-phenyl-C₆₁-butyric acid methyl ester (PCBM). In other embodiments the electron acceptor is selected to have a LUMO energy level lower than that of bis(1-[3-(methoxycarbonyl)propyl]-1-phenyl)[6,6]C₆₂ (bis-PCBM). The donor materials used in the photovoltaic devices can be selected from various semiconducting small molecules, oligomers, dendrimers, polymers or copolymers.

In another aspect of the present invention, the active layer of the photovoltaic cell device comprises a fullerene as an electron acceptor. In certain embodiments, the electron acceptor comprises a pristine fullerene. In one or more other embodiments, the electron acceptor comprises a functionalized fullerene or fullerene derivative having the formula:

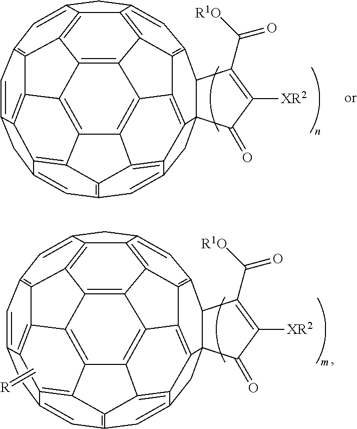

wherein the fullerene core exhibits the formula C₂ₙ, such as C₆₀, C₇₀ or C₈₄. X is selected from the group consisting of nitrogen, oxygen and sulfur. R¹ and R² are independently selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; a carbonyl, carboxylate, nitro, sulfonyl, amino, amide, cyano, hydroxyl, thiol, silyl, siloxy or halogen group; and combinations of said R¹ and R² groups. m is equal to 1 or 2 and n is equal to 1, 2 or 3. R is selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; and a carbonyl, carboxylate, nitro, sulfonyl, amino, amide, cyano, hydroxyl, thiol, silyl, siloxy or halogen group. The R group comprises one or two optionally substituted organic groups which are covalently bonded to the surface of the fullerene core by two single covalent bonds. The two bonds can be between the R group(s) and two carbons adjacent to each other on the fullerene surface, or can be between the R group(s) and two carbons in the same six or five membered rings on the fullerene surface, or can be between the R group(s) and two carbons in difference six or five membered rings on the fullerene surface. The two bonds can be between two carbon atoms on the fullerene surface and a same carbon or heteroatom on one R group, or between two carbon atoms on the fullerene surface and two difference carbons or heteroatoms on one R group, or between two carbon atoms on the fullerene surface and two different carbon or heteroatoms on two R groups respectively.

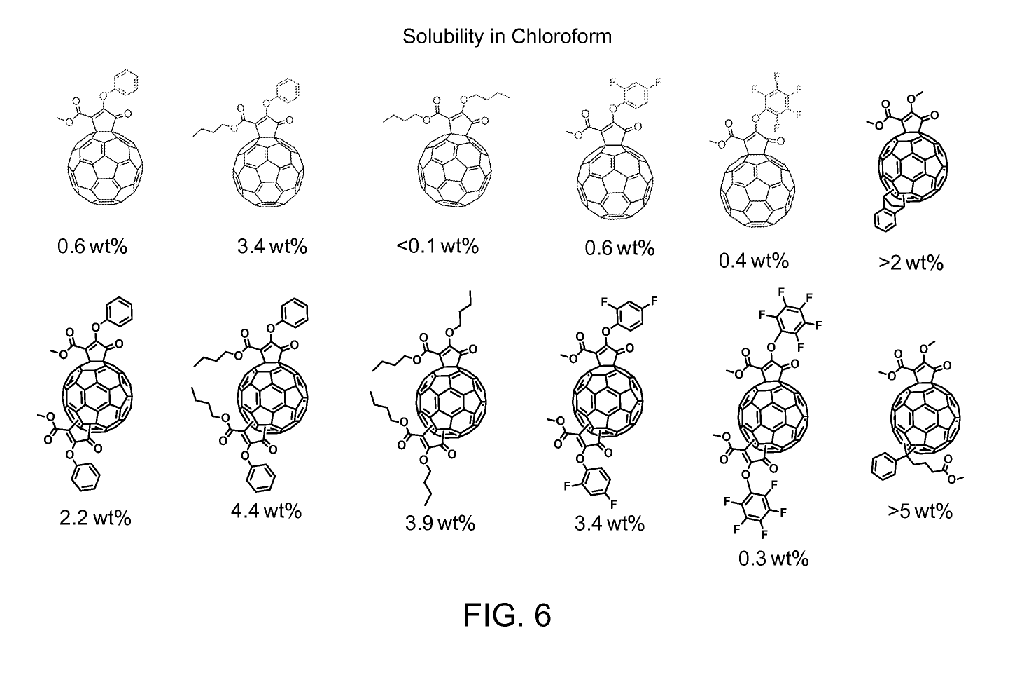

In one or more embodiments, the electron acceptor comprises at least 2 covalent bonds between the fullerene core and R. In certain embodiments, the at least 2 covalent bonds are bound to different carbons in the fullerene core. In other embodiments, the at least 2 covalent bonds are bound to 1,2-carbons or 1,4-carbons of a six-member ring in the fullerene core. The fullerene derivatives with the R groups can be methanofullerene derivatives, PCBM derivatives, Prato derivatives, Bingel derivatives, fulleropyrrolidines, diazoline derivatives, azafulleroid derivatives, Diels-Alder derivatives, indene fullerenes, dihydronaphthyl derivatives, 1,4-di(organo)fullerenes. Various examples of fullerenes include, but are not limited to, those shown in FIG. 6.

In one or more other embodiments, R is a functional/structural group which can be selected from, but not limited to, the following:

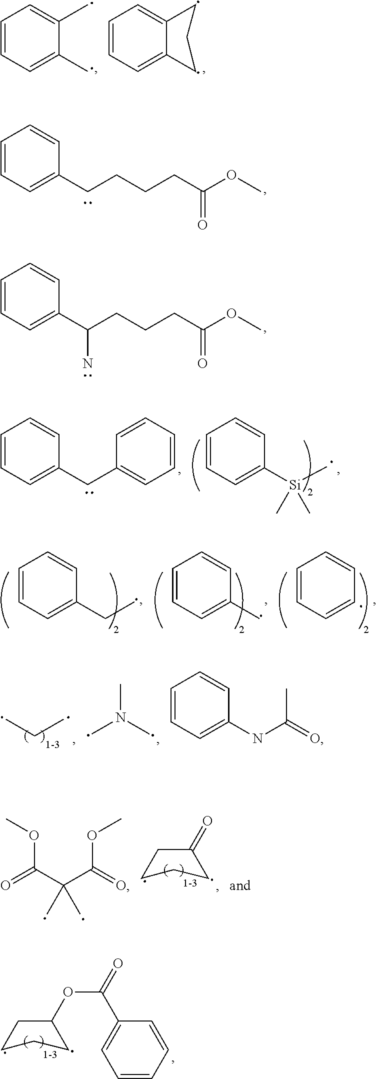

where the two dots on each functional group indicate the two bonding positions to the fullerene core.

The electron acceptor may also comprise a mixture of different fullerenes. In one or more embodiments, the mixture of different fullerenes comprises at least one of a compound having a five membered cyclopentene ring as shown in Schemes 1 and 2 above; a compound disclosed in the Figures; a compound shown in Tables 1-6; a mono-fullerene; a bis-fullerene; a tris fullerene; or a pristine fullerene. In one example, the electron acceptor is selected to comprise a mixture of mono-fullerenes and bis-fullerenes. In one or more embodiments, the mixture of different fullerenes comprises at least two compounds selected to have LUMO levels within 0.05 eV of each other.

In certain instances, the fullerene has the formula:

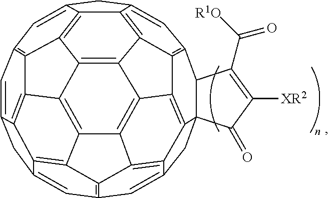

wherein C₆₀, R¹=Me, R²=Ph, X═O, n=1; C₆₀, R¹=Me, R²=Ph, X═O, n=2; C₆₀, R¹=Me, R²=Me, X═O, n=1; C₆₀, R¹=Me, R²=Me, X═O, n=2; C₆₀, R¹=Me, R²═F₂Ph, X═O, n=1; C₆₀, R¹=Me, R²═F₂Ph, X═O, n=2; C₆₀, R¹=Me, R²═F₅Ph, X═O, n=1; C₆₀, R¹=Me, R²═F₅Ph, X═O, n=2; C₆₀, R¹=Me, R²=Ph, X═S, n=1; C₆₀, R¹=n-Bu, R²=Ph, X═O, n=1; C₆₀, R¹=n-Bu, R²=Ph, X═O, n=2; C₆₀, R¹=n-Bu, R²=n-Bu, X═O, n=1; C₆₀, R¹=n-Bu, R²=n-Bu, X═O, n=2; C₇₀, R¹=n-Bu, R²=Ph, X═O, n=1; or C₇₀, R¹=n-Bu, R²=Ph, X═O, n=2. In other instances, the fullerene has the formula:

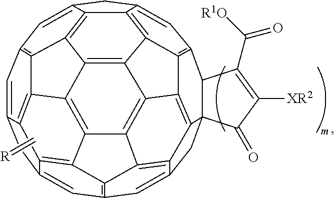

wherein R═

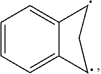

### R¹═R²=Me or R═

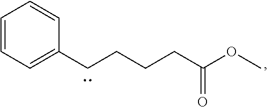

R¹═R²=Me, m is equal to 1 or 2.

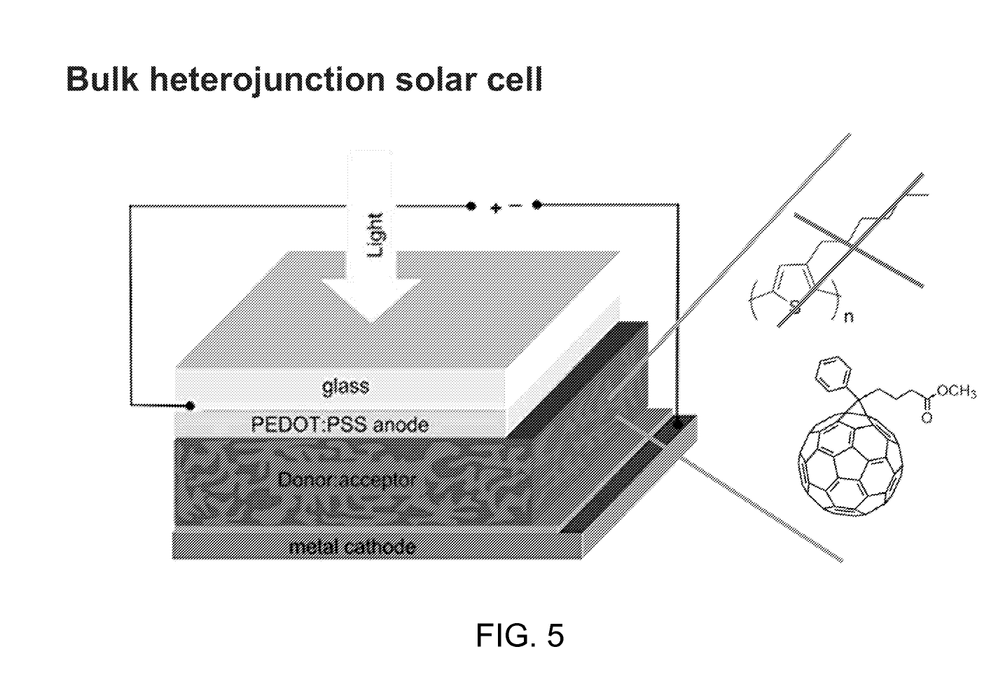

In another aspect of the present invention, a device is provided comprising a first electrode, a second electrode, and an active layer disposed between the first and second electrodes. FIG. 5 provides an illustration of a photovoltaic cell device structure according to one or more embodiments, comprising a metal cathode, an active layer (e.g., donor-acceptor heterojunction material) on, above, or overlying the metal cathode, a PEDOT:PSS anode on, above, or overlying the active layer, and a glass substrate on, above, or overlying the PEDOT:PSS anode. A module is also provided comprising a plurality of the photovoltaic cells and at least some of the photovoltaic cells being electrically connected.

In one or more embodiments, the photovoltaic cell device exhibits a power conversion efficiency higher than a power conversion efficiency of a control device or identical device with the same structure but with PCBM as an electron acceptor. In certain embodiments, the photovoltaic cell device exhibits a power conversion efficiency at least 5% higher than a power conversion efficiency of an identical device with the same structure but with PCBM as an electron acceptor. In certain embodiments, the photovoltaic cell device exhibits a power conversion efficiency at least 10% higher than a power conversion efficiency of an identical device with the same structure but with PCBM as an electron acceptor. In certain embodiments, the photovoltaic cell exhibits an efficiency of at least about 1.0%. As discussed in further detail below, the power conversion efficiency of a photovoltaic cell is the most commonly used parameter to compare the performance of one photovoltaic cell to another. Efficiency is defined as the ratio of energy output from the photovoltaic cell to input energy from the sun. In addition to reflecting the performance of the photovoltaic cell itself, the efficiency depends on the spectrum and intensity of the incident sunlight (P_{inc}) and the temperature of the photovoltaic cell. Therefore, conditions under which efficiency is measured must be carefully controlled in order to compare the performance of one device to another. Terrestrial solar cells are measured under AM1.5 conditions and at a temperature of 25° C. Solar cells intended for space use are measured under AM0 conditions. The efficiency (η) of a solar cell is determined as the fraction of incident power which is converted to electricity and is defined as:

η=(V_{OC})(J_{SC})(ff)/P_{inc} (equation 1)

where V_{oc} is the open-circuit voltage, J_{sc} is the short-circuit current, ff is the fill factor, P_{inc} is the intensity of the incident sunlight, and 11 is the efficiency.

In one or more embodiments, the active layer comprises a mixture of a first fullerene and a second fullerene different from the first fullerene. In further embodiments, the first fullerene comprises at least 50%, 60%, 70%, 80%, 90%, 95%, 99%, or 99.5% of the mixture by weight. In certain instances, the active layer comprises a mono-fullerene and a bis-fullerene.

In one or more embodiments, the mixture of different fullerenes comprises at least one of a compound having the formula:

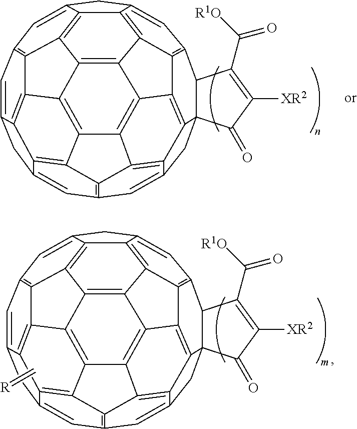

wherein the fullerene core exhibits the formula C₂ₙ, such as C₆₀, C₇₀ or C₈₄. X is selected from the group consisting of nitrogen, oxygen and sulfur. R, R¹, and R² are independently selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; a carbonyl, carboxylate, nitro, sulfonyl, amino, amide, cyano, hydroxyl, thiol, silyl, siloxy or halogen group; and combinations of said R¹ and R² groups. m is equal to 1 or 2 and n is equal to 1, 2 or 3. In one embodiment, the loading of the fullerene is from 0.5 wt % to 99.5 wt % of the total amount of the acceptors used.

In another embodiment, m is equal to 1 or 2, or n is equal to 2 or 3 and the device exhibits a power conversion efficiency higher than a power conversion efficiency of a control device with PCBM as an electron acceptor. In yet another embodiment, the device exhibits a power conversion efficiency at least 5% higher than a power conversion efficiency of a control device with PCBM as an electron acceptor. In yet another embodiment, the device exhibits a power conversion efficiency at least 10% higher than a power conversion efficiency of a control device with PCBM as an electron acceptor. In yet another embodiment, m is equal to 1 or 2, or n is equal to 2 or 3 and thermally annealing the active layer at 160° C. for one hour results in a power conversion efficiency of at least 60% of the original power conversion efficiency of the active layer. In other embodiments, thermally annealing the active layer at 160° C. for one hour results in a device with a power conversion efficiency that is higher than a control device that utilizes PCBM as an electron acceptor. In one embodiment, thermally annealing the active layer at 160° C. for one hour results in a device with a power conversion efficiency that is at least 2 times higher than a control device that utilizes PCBM as an electron acceptor.

In another aspect of the present invention, a method of forming an organic photovoltaic cell is provided. The method comprises forming an active layer composition including an electron donor and an electron acceptor. In one embodiment, the electron acceptor comprises a fullerene selected to exhibit a LUMO energy level lower than that of bis(1-[3-(methoxycarbonyl)propyl]-1-phenyl)[6,6]C₆₂ (bis-PCBM). In another embodiment, the electron acceptor comprises a fullerene selected to exhibit a LUMO energy level lower than that of [6,6]-phenyl-C₆₁-butyric acid methyl ester (PCBM). In one or more embodiments, the electron donor is selected to exhibit a LUMO level not more than 0.4 eV higher than the LUMO level of bis(1-[3-(methoxycarbonyl)propyl]-1-phenyl)[6,6]C₆₂ (bis-PCBM) and/or the electron acceptor comprises a fullerene selected to exhibit a LUMO energy level lower than that of bis-PCBM. In certain embodiments, the electron donor is selected to exhibit a LUMO level not more than 0.4 eV higher than the LUMO level of [6,6]-phenyl-C₆₁-butyric acid methyl ester (PCBM) and/or the electron acceptor comprises a fullerene selected to exhibit a LUMO energy level lower than that of PCBM.

Specifically, the electron donor may be selected to exhibit a LUMO level not more than 0.40 eV, 0.35 eV, 0.30 eV, 0.25 eV, 0.2 eV, 0.15 eV, 0.1 eV or 0.05 eV higher than the LUMO level of [6,6]-phenyl-C₆₁-butyric acid methyl ester (PCBM) and/or the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than that of PCBM. In other instances, the electron donor is selected to exhibit a LUMO level not more than 0.40 eV, 0.35 eV, 0.30 eV, 0.25 eV, 0.2 eV, 0.15 eV, 0.1 eV or 0.05 eV higher than the LUMO level of bis(1-[3-(methoxycarbonyl)propyl]-1-phenyl)[6,6]C₆₂ (bis-PCBM) and/or the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of bis-PCBM.

In one or more other embodiments, the electron donor is selected to exhibit a LUMO level not more than 0.40 eV, 0.35 eV, 0.30 eV, 0.25 eV, 0.2 eV, 0.15 eV, 0.1 eV or 0.05 eV higher than about −3.8 eV and/or the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than about −3.8 eV. In other embodiments, The electron donor is selected to exhibit a LUMO level not more than 0.40 eV, 0.35 eV, 0.30 eV, 0.25 eV, 0.2 eV, 0.15 eV, 0.1 eV or 0.05 eV higher than about −3.72 eV and/or the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than about −3.72 eV.

In another aspect of the present invention, the active layer of the photovoltaic cell device comprises a fullerene as an electron acceptor. In certain embodiments, the electron acceptor comprises a pristine fullerene. In one or more other embodiments, the electron acceptor comprises a functionalized fullerene or fullerene derivative having the formula:

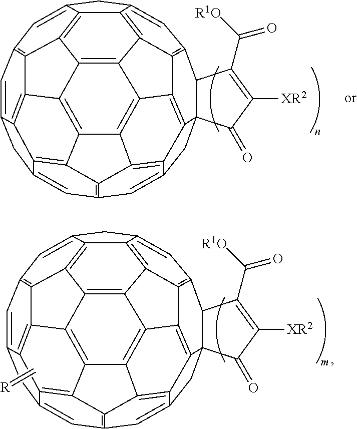

wherein the fullerene core exhibits the formula C₂ₙ, such as C₆₀, C₇₀ or C₈₄. X is selected from the group consisting of nitrogen, oxygen and sulfur. R¹ and R² are independently selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; a carbonyl, carboxylate, nitro, sulfonyl, amino, amide, cyano, hydroxyl, thiol, silyl, siloxy or halogen group; and combinations of said R¹ and R² groups. m is equal to 1 or 2 and n is equal to 1, 2 or 3. R is a functional group selected from the group consisting of:

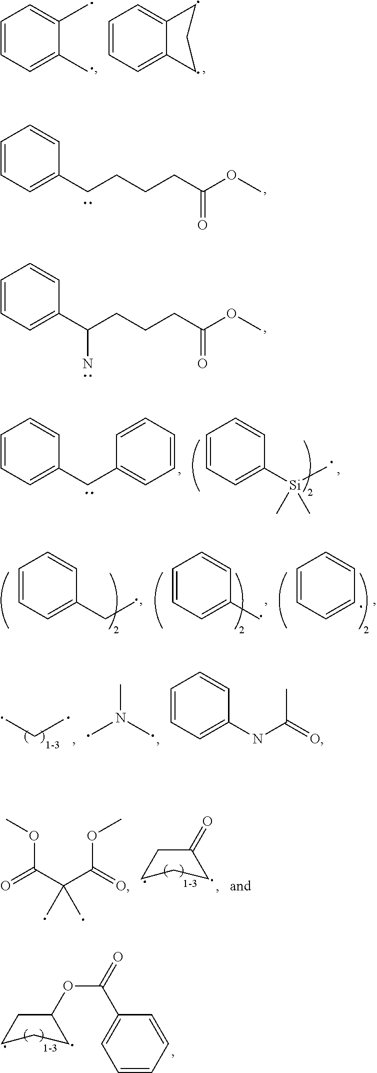

where the two dots on each functional group indicate the two bonding positions to the fullerene core.

The active layer may also comprise a mixture of different fullerenes. In one or more embodiments, the mixture of different fullerenes comprises at least one of a compound having a five-membered cyclopentene ring as shown in Schemes 1-2 above, a compound disclosed in the Figures, a compound shown in Tables 1-6, a mono-fullerene, a bis-fullerene, a tris-fullerene or a pristine fullerene. In one example, the active layer comprises a mixture of mono-fullerenes and bis-fullerenes. In one or more embodiments, the mixture of different fullerenes comprises at least two compounds selected to have LUMO levels within 0.05 eV of each other.

In certain instances, the fullerene has the formula:

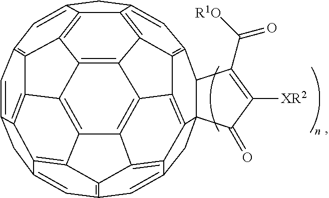

wherein C₆₀, R¹=Me, R²=Ph, X═O, n=1; C₆₀, R¹=Me, R²=Ph, X═O, n=2; C₆₀, R¹=Me, R²=Me, X═O, n=1; C₆₀, R¹=Me, R²=Me, X═O, n=2; C₆₀, R¹=Me, R²═F₂Ph, X═O, n=1; C₆₀, R¹=Me, R²═F₂Ph, X═O, n=2; C₆₀, R¹=Me, R²═F₅Ph, X═O, n=1; C₆₀, R¹=Me, R²═F₅Ph, X═O, n=2; C₆₀, R¹=Me, R²=Ph, X═S, n=1; C₆₀, R¹=n-Bu, R²=Ph, X═O, n=1; C₆₀, R¹=n-Bu, R²=Ph, X═O, n=2; C₆₀, R¹=n-Bu, R²=n-Bu, X═O, n=1; C₆₀, R¹=n-Bu, R²=n-Bu, X═O, n=2; C₇₀, R¹=n-Bu, R²=Ph, X═O, n=1; or C₇₀, R¹=n-Bu, R²=Ph, X═O, n=2. In other instances, the fullerene has the formula:

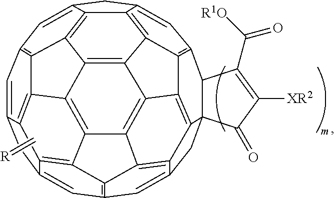

wherein R═

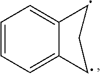

### R¹═R²=Me or R═

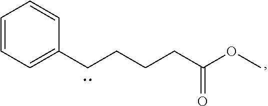

R¹═R²=Me, m is equal to 1 or 2

In another aspect of the present invention, the method of forming an organic photovoltaic cell comprises selecting a electron donor that exhibits a LUMO level not less than 0.1 eV lower than the LUMO level of regioregular poly(3-hexylthiophene) (rr-P3HT) and/or an electron acceptor that exhibits a LUMO energy level lower than that of [6,6]-phenyl-C₆₁-butyric acid methyl ester (PCBM). In one example, the method comprises selecting an electron donor exhibits a LUMO level not less than 0.1 eV lower than the LUMO level of rr-P3HT in combination with a fullerene that exhibits a LUMO energy level lower than that of PCBM.

In one or more embodiments, the method further comprises (a) selecting the electron donor and the electron acceptor to exhibit compatible solubility profiles such that a single solvent is used for forming the active layer on a surface of the device and/or (b) selecting the electron donor and the electron acceptor to exhibit compatible solubility profiles such that each exhibit an at least 0.5 weight percent (wt %) solubility in a solvent used to form the active layer. In certain instances, the electron donor compound and the electron acceptor compound are selected to exhibit compatible solubility profiles such that each exhibit an at least 1, 2, 3, 4, 5, 6, 7, or 8 wt % solubility in a solvent used to form the active layer. The solvent may comprise at least one of the group selected from chlorobenzene, 1,2-dichlorobenzene, chloroform, toluene, xylene, ethyl benzoate and tetralin.

There is no particular limitation on the solvent used in formation of a film from a solution, as long as the solvent dissolves a fullerene derivative used in the present invention. Examples of the solvent include hydrocarbon solvents such as toluene, xylene, mesitylene, tetralin, decalin, cyclohexane, butylbenzene, sec-butylbenzene and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane and bromocyclohexane; halogenated unsaturated hydrocarbon solvents such as chlorobenzene, dichlorobenzene and trichlorobenzene; ester solvents such as ethyl benzoate, and ether solvents such as anisole, tetrahydrofuran and tetrahydropyran. The fullerene derivative can be usually dissolved in the solvent in the concentration of 0.1% by weight or more. The solvent may further comprise a processing additive selected from but not limited to the following: 1,6-dithiolhexane; 1,6-dichlorohexane; 1,6-dibromohexane; 1,6-diiodohexane; octadinitrile; 1,8-dithioloctane; 1,8-dichlorooctane; 1,8-dibromooctane; 1,8-diiodooctane, decanedinitrile; 1,10-dithioldecane; 1,10-dichlorodecane; 1,10-dibromodecane; 1,10-diiododecane; dodecanedinitrile; chloronaphthalene[50].

Active layer of the photovoltaic cell device may be deposited on a surface by a number of thin film deposition methods such as a spin coating method, a casting method, a microgravure coating method, a gravure coating method, a bar coating method, a roll coating method, a blade coating method, a wire bar coating method, a dip coating method, a spray coating method, a free span coating method, a dye coating method, a screen printing method, a flexo printing method, an offset printing method, an inkjet printing method, a dispenser printing method, a nozzle coating method and a capillary coating method, for forming a film from a solution.

In one specific embodiment, a photovoltaic cell device is provided. The photovoltaic cell device includes an active layer comprising an electron donor selected to have a LUMO level not more than 0.4 eV higher than the LUMO level of [6,6]-phenyl-C₆₁-butyric acid methyl ester (PCBM) or bis(1-[3-(methoxycarbonyl)propyl]-1-phenyl)[6,6]C₆₂ (bis-PCBM) and an electron acceptor comprising a fullerene having the formula:

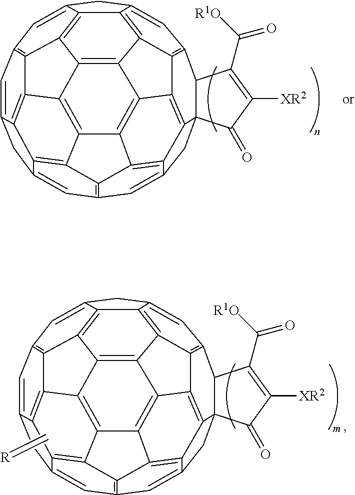

The fullerene core exhibits the formula C₂ₙ, such as C₆₀, C₇₀ or C₈₄. X is selected from the group consisting of nitrogen, oxygen and sulfur. R¹ and R² are independently selected from the group consisting of hydrogen; a Cₙ alkyl group, alkenyl group or alkynyl group, wherein n=1 to 30, a Cₙ aryl group, wherein n=4 to 30; a Cₙ heteroaryl group, wherein n=2 to 30; a Cₙ fluoroalkyl group, wherein n=1 to 30; a Cₙ fluoroaryl group, wherein n=2 to 30; (CH₂CH₂O)ₙ, wherein n=1 to 20; a carbonyl, carboxylate, nitro, sulfonyl, amino, amide, cyano, hydroxyl, thiol, silyl, siloxy or halogen group; and combinations of said R¹ and R² groups. m is equal to 1 or 2 and n is equal to 1, 2 or 3. R is a functional group selected from the group consisting of:

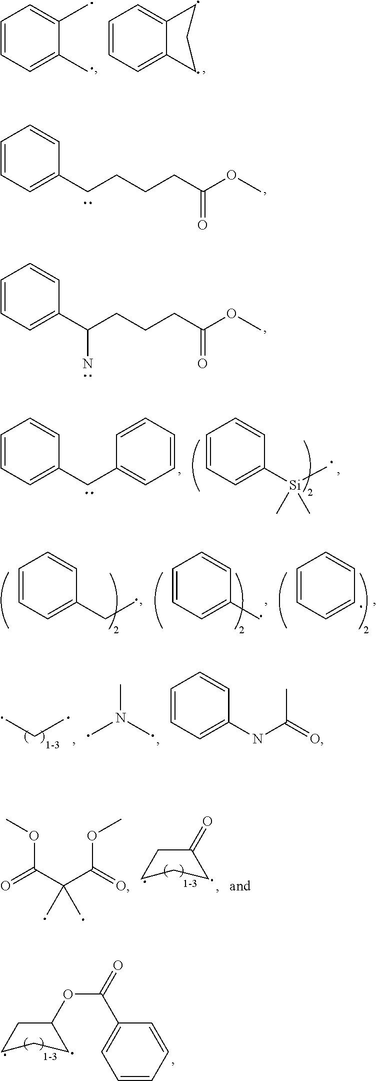

where the two dots on each functional group indicate the two bonding positions to the fullerene core. The electron acceptor has a LUMO energy level lower than that of PCBM or bis-PCBM.

### EXAMPLES

In the Examples provided below, a series of illustrative fullerene derivatives (I) and (II) were synthesized following Schemes 1 and 2, and an extensive characterization on their thermal, optical, electrical and photovoltaic properties was conducted. The fullerene derivatives (I) provided for illustrative purposes in the Examples below include: 1a, C60CP-PhMe1 (R¹=Me, R²=Ph, X═O, n=1); 1b, C60CP-PhMe2 ((R¹=Me, R²=Ph, X═O, n=2); 2a, C60CP-MeMe1 (R¹=Me, R²=Me, X═O, n=1); 2b, C60CP-MeMe2 (R¹=Me, R²=Me, X═O, n=2); 3a, C60CP-F2PhMe1 (R¹=Me, R²═F₂Ph, X═O, n=1); 3b, C60CP-F2PhMe2 (R¹=Me, R²═F₂Ph, X═O, n=2); 4a, C60CP-F5PhMe1 (R¹=Me, R²═F₅Ph, X═O, n=1); 4b, C60CP-F5PhMe2 (R¹=Me, R²═F₅Ph, X═O, n=2); 5a, C60CP-SPhMe1 (R¹=Me, R²=Ph, X=5, n=1). 6a, C60CP-PhBu1 (R¹=n-Bu, R²=Ph, X═O, n=1); 6b, C60CP-PhBu2 (R¹=n-Bu, R²=Ph, X═O, n=2); 7a, C60CP-BuBu1 (R¹=n-Bu, R²=n-Bu, X═O, n=1); 7b, C60CP-BuBu2 (R′=n-Bu, R²=n-Bu, X═O, n=2); 8a, C70CP-PhBu1 (C₇₀, R¹=n-Bu, R²=Ph, X═O, n=1); 8b, C70CP-PhBu2 (C₇₀, R¹=n-Bu, R²=Ph, X═O, n=2). The fullerene derivatives (II) provided for illustrative purposes in the Examples below include: 9, PC61BM-CP-MeMe1, (R═

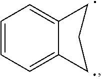

### R¹═R²=Me); 10, IC60MA-CP-MeMe1 (R═

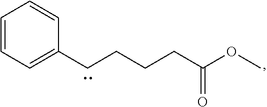

### R¹═R²=Me).

### Example 1

### Preparation of Fullerene Derivatives

Fullerene derivatives 1a,b-5a, bearing a methyl group and another variable group, were prepared by adapting above published procedure as follows [25-27]: Dimethylaminopyridine (152 mg, 1.25 mmol) and C₆₀ (300 mg, 0.416 mmol) in 200 mL dry toluene under argon were sonicated for 20 minutes when a violet solution was formed. Dimethyl acetylenedicarboxylate (102 μL, 0.832 mmol) in 3 mL dry toluene was added dropwise and after stirring for 30 minutes a solution of the alcohol (8.32 mmol) in 5 mL dry toluene was added. After stirring for another 30 minutes, the solution was heated to 60° C. until a clear brownish solution was obtained. The solvent was removed under reduced pressure and the crude product was purified by column chromatography (Eluent: toluene/hexane) which enabled isolation of both the mono- and bis-adduct. Recrystallization from CHCl₃/MeOH afforded the different compounds as brown powders. Yields and analytical data for the individual compounds are described as follows.

C60CP-PhMe1 (1a): The standard procedure described above was modified by increasing the equivalents of dimethylaminopyridine (6 eq, 305 mg) and dimethyl acetylenedicarbocylate (4 eq, 205 μL). Yield: 30%. ¹H-NMR (600 MHz, CDCl₃/CS₂): δ 7.51 (t, 2H, J_{HH}=7.6 Hz, —Ar—H), 7.41 (d, 2H, J_{HH}=8.3 Hz, —Ar—H), 7.29 (t, 1H, J_{HH}=7.3 Hz, —Ar—H), 3.81 (s, 3H, —CH₃). ¹³C-NMR (150 MHz, CDCl₃/CS₂): δ 195.7, 163.3, 154.5, 152.5, 150.6, 147.5, 147.3, 147.1, 146.6, 146.3, 146.2, 145.9, 145.7, 145.6, 145.5, 144.9, 144.6, 144.4, 143.1, 142.9, 142.8, 142.4, 142.1, 141.8, 141.4, 140.8, 139.6, 136.3, 135.7, 53.6. m/z (FD-MS) [M]⁺=924.00, calculated for (C₇₁H₈O₄)=924.04.

C60CP-PhMe2 (1b): Yield: 6%. ¹H-NMR (600 MHz, CDCl₃): δ 7.57-7.20 (m, 10H, —Ar—H), 3.96-3.62 (m, 6H, —CH₃). m/z (FD-MS) [M]⁺=1128.06, calculated for (C₈₂H₁₆O₈)=1128.09.

C60CP-MeMe1 (2a): Yield: 33%. ¹H-NMR (600 MHz, CDCl₃/CS₂): δ 4.57 (s, 3H, —COCH₃), 4.01 (s, 3H, —CO₂CH₃). ¹³C-NMR (150 MHz, CDCl₃/CS₂): δ 196.8, 163.9, 156.7, 153.0, 151.3, 147.5, 147.3, 146.6, 146.5, 146.3, 146.2, 145.8, 145.7, 145.5, 144.6, 144.5, 143.1, 142.9, 142.4, 142.1, 141.9, 141.8, 141.4, 140.7, 139.5, 138.7, 136.1, 135.8, 59.7, 52.4. m/z (FD-MS) [M]⁺=862.02, calculated for (C₆₆H₆O₄)=862.03.

C60CP-MeMe2 (2b): Yield: 16%. ¹H-NMR (600 MHz, CDCl₃): δ 4.66-4.38 (m, 6H, —COCH₃), 4.19-3.83 (s, 6H, —CO₂CH₃). m/z (FD-MS) [M]⁺=1004.04, calculated for (C₇₂H₁₂O₈)=1004.05.

C60CP-F2PhMe1 (3a): Yield: 33%. ¹H-NMR (600 MHz, CDCl₃): δ 7.32-7.26 (m, 2H, —Ar—H), 7.18-7.14 (m, 1H, —Ar—H), 3.95 (s, 3H, —OCH₃). ¹³C-NMR (150 MHz, CDCl₃): δ 195.9, 154.2, 152.2, 152.1, 150.1, 147.5, 147.3, 146.9, 146.6, 146.5, 146.3, 146.2, 145.9, 145.6, 145.5, 144.6, 144.4, 143.0, 142.9, 142.8, 142.2, 142.1, 141.8, 141.7, 141.3, 140.8, 139.7, 136.3, 135.7, 53.4. ¹⁹F-NMR (560 MHz, CDCl₃): δ −133.2-133.3 (m, 1F, F—Ar), −141.5-141.7 (m, 1F, F—Ar). m/z (FD-MS) [M]⁺=959.95, calculated for (C₇₁H₆F₂O₄)=960.02.

C60CP-F2PhMe2 (3b): Yield: 8.5%. ¹H-NMR (600 MHz, CDCl₃): δ 7.37-6.96 (m, 6H, —Ar—H), 4.12-3.48 (m, 6H, —OCH₃). ¹⁹F-NMR (560 MHz, CDCl₃): δ −133.1-133.4 (m, 2F, F—Ar), −141.5-141.8 (m, 2F, F—Ar). m/z (FD-MS) [M]⁺=1199.95, calculated for (C₈₂H₁₂F₄O₈)=1200.05

C60CP-F5PhMe1 (4a): Yield: 25%. ¹H-NMR (600 MHz, CDCl₃/CS₂): δ 4.07 (s, 3H, —OCH₃). ¹³C-NMR (150 MHz, CDCl₃/CS₂): 8194.8, 167.5, 153.8, 151.9, 149.9, 147.6, 147.3, 146.8, 146.7, 146.4, 146.3, 146.2, 145.9, 145.7, 145.6, 145.5, 144.6, 144.4, 143.3, 143.1, 142.9, 142.5, 142.1, 141.8, 141.7, 141.4, 140.8, 139.5, 136.4, 135.8, 53.6. ¹⁹F-NMR (560 MHz, CDCl₃): δ −155.0 (d, 2F, J_{FF}=18 Hz, F—Ar), −158.5 (t, 1F, J_{FF}=22 Hz, F—Ar), −161.0 (m, 2F, F—Ar). m/z (FD-MS) [M]⁺=1013.97, calculated for (C₇₁H₃O₄F₅)=1014.00.

C60CP-F5PhMe2 (4b): Yield: 6.0%. ¹H-NMR (600 MHz, CDCl₃): δ 4.09-3.93 (m, 6H, —OCH₃). ¹⁹F-NMR (560 MHz, CDCl₃): δ −155.4-156.0 (m, 4F, F—Ar), −159.0-159.3 (m, 2F, F—Ar), −161.5-161.9 (m, 4F, F—Ar). m/z (FD-MS) [M]⁺=1307.96, calculated for (C82H₆O₈F₁₀)=1307.99.

C60CP-SPhMe1 (5a): Yield: 15%. ¹H-NMR (600 MHz, CDCl₃): δ 7.83 (d, 2H, J_{HH}=8.2 Hz, —Ar—H), 7.51-7.47 (m, 3H, —Ar—H), 3.86 (s, 3H, —OCH₃). (FD-MS) [M]⁺=939.98, calculated for (C₇₁H₈O₃S)=940.02.

Dibutyl acteylenedicaboxylate was synthesized according to the following procedure [28]. Acetylenedicarboxylic acid (5.0 g, 43.8 mmol), p-toluenesulfonic acid monohydrate (0.54 g, 2.85 mmol) and butanol (13.0 g, 0.18 mol) were dissolved in 70 mL benzene and stirred overnight at 95° C. in a round bottom flask equipped with a Dean-Stark trap. The solvent was removed under reduced pressure and the product was purified by column chromatography (Eluent: hexane to hexane:EtOAc 17:3). ¹H-NMR (600 MHz, CDCl₃): δ 4.23 (t, 2H, J_{HH}=6.7 Hz, —OCH₂C₃H₇), 1.66 (m, 2H, —OCH₂CH₂C₂H₅), 1.39 (m, 2H, —OC₂H₄CH₂CH₃), 0.93 (t, 3H, J_{HH}=7.4 Hz, —OC₃H₆CH₃).

Fullerene derivatives 6a, 6b, 7a, 7b, bearing a butyl group and another variable group, were prepared by adapting above published procedure as following [25-27]: Dimethylaminopyridine (152 mg, 1.25 mmol) and C₆₀ (300 mg, 0.416 mmol) in 200 mL dry toluene under argon were sonicated for 20 minutes when a violet solution was formed. Dibutyl acetylenedicarboxylate (188 mg, 0.832 mmol) in 3 mL dry toluene was added dropwise and after stirring for 15 minutes a solution of the alcohol (8.32 mmol) in 5 mL dry toluene was added. The solution was stirred until a clear brownish solution was obtained. The solvent was removed under reduced pressure and the crude product was purified by column chromatography (Eluent: toluene/hexanes) which enabled isolation of both the mono- and bis-adduct. Recrystallization from CHCl₃/MeOH afforded the different compounds as brown powders. Yields and analytical data for the individual compounds are described in the following.

C60CP-PhBu1 (6a): Yield: 45%. ¹H-NMR (600 MHz, CDCl₃): δ 7.50 (t, 2H, J_{HH}=7.7 Hz, —Ar—H), 7.40 (d, 2H, J_{HH}=8.5 Hz, —Ar—H), 7.27 (t, J_{HH}=7.5 Hz, 1H, —Ar—H), 4.25 (t, J_{HH}=6.6 Hz, 2H, C₃H₇—CH₂O—), 1.59 (m, 2H, C₂H₅—CH₂—CH₂—), 1.32 (m, 2H, CH₃—CH₂—C₂H₄—), 0.85 (t, 3H, J_{HH}=7.4 Hz, CH₃—C₃H₆—). ¹³C-NMR (150 MHz, CDCl₃): δ 196.3, 163.1, 155.6, 154.2, 152.5, 150.6, 147.5, 147.3, 147.1, 146.6, 146.3, 146.2, 145.8, 145.7, 145.5, 144.6, 144.4, 143.1, 142.9, 142.4, 142.1, 141.8, 141.4, 140.8, 139.6, 136.3, 135.7, 130.0, 124.8, 117.6, 66.4, 30.3, 19.4, 13.6. m/z (FD-MS) [M]⁺=966.03, calculated for (C₇₄H₁₄O₄)=966.09.

C60CP-PhBu2 (6b): Yield: 21%. ¹H-NMR (600 MHz, CDCl₃): δ 7.56-7.13 (m, 10H, —Ar—H), 4.41-4.05 (m, 4H, C₃H₇—CH₂O—), 1.75-1.57 (m, 4H, C₂H₅—CH₂—CH₂—), 1.52-1.17 (m, 4H, CH₃—CH₂—C₂H₄—), 0.96-0.75 (m, 6H, CH₃—C₃H₆—). m/z (FD-MS) [M]⁺=1212.12, calculated for (C₈₈H₂₈O₈)=1212.18.

C60CP-BuBu1 (7a): Yield: 30%. ¹H-NMR (600 MHz, CDCl₃/CS₂): δ 4.90 (t, 2H, J_{HH}=6.5 Hz, C₃H₇—CH₂O—), 4.41 (t, 2H, J_{HH}=6.6 Hz, C₃H₇—CH₂O—), 1.98 (m, 2H, C₂H₅—CH₂—CH₂—), 1.76 (m, 2H, C₂H₅—CH₂—CH₂—), 1.69 (m, 2H, CH₃—CH₂—C₂H₄—), 1.49 (m, 2H, CH₃—CH₂—C₂H₄—), 1.12 (t, 3H, J_{HH}=7.4 Hz, CH₃—C₃H₆—), 0.99 (t, 3H, J_{HH}=7.4 Hz, CH₃—C₃H₆—). ¹³C-NMR (150 MHz, CDCl₃/CS₂): δ 197.3, 163.8, 156.5, 153.1, 151.5, 147.5, 147.4, 147.2, 146.6, 146.5, 146.3, 146.2, 145.7, 145.5, 145.5, 145.4, 144.6, 144.6, 143.0, 142.8, 142.8, 142.4, 142.1, 141.9, 141.7, 141.4, 140.7, 139.5, 139.3, 136.0, 135.8, 72.3, 65.9, 32.6, 30.9, 19.6, 19.4, 14.2, 14.0. m/z (FD-MS) [M]⁺=946.09, calculated for (C₇₂H₁₈O₄)=946.12.

C60CP-BuBu2 (7b): Yield: 18%. ¹H-NMR (600 MHz, CDCl₃): δ 4.96-4.68 (m, 4H, C₃H₇—CH₂O—), 4.60-4.25 (m, 4H, C₃H₇—CH₂O—), 2.03-1.31 (m, 16H, C₂H₅—CH₂—CH₂—), 1.15-0.84 (m, 12H, CH₃—C₃H₆—). m/z (FD-MS) [M]⁺=1172.19, calculated for (C₈₄H₃₆O₈)=1172.24.

Fullerene derivative 8a and 8b with a C₇₀ core were prepared by adapting the above published procedure. Dimethylaminopyridine (102 mg, 0.883 mmol) and C₇₀ (200 mg, 0.238 mmol) in 150 mL dry toluene under argon were sonicated for 20 minutes when a violet solution was formed. Dibutyl acteylenedicaboxylate (126 mg, 0.555 mmol) in 3 mL dry toluene was added dropwise and after stirring for 15 minutes a solution of phenol (5.55 mmol) in 5 mL dry toluene is added. The solution was stirred until a clear brownish solution was obtained. The solvent was removed under reduced pressure and the crude product was purified by column chromatography (Eluent: toluene) which enabled isolation of both the mono- and bis-adduct. Recrystallization from CHCl₃/MeOH afforded the different compounds as brown powders.

C70CP-PhBu1 (8a): Yield: 36%. ¹H-NMR (600 MHz, CDCl₃): δ 7.42 (t, 2H, J_{HH}=7.8 Hz, —Ar—H), 7.24-7.13 (m, 3H, —Ar—H), 4.39 (t, 2H, J_{HH}=6.5 Hz, C₃H₇—CH₂O—), 1.75 (m, 2H, C₂H₅—CH₂—CH₂—), 1.47 (m, 2H, CH₃—CH₂—C₂H₄—), 0.98 (t, 3H, J_{HH}=7.5 Hz, CH₃—C₃H₆—). ¹³C-NMR (150 MHz, CDCl₃): δ 193.2, 163.2, 156.5, 155.9, 155.4, 153.3, 151.5, 151.4, 151.3, 150.7, 150.6, 150.3, 150.1, 150.1, 149.8, 149.6, 148.9, 148.8, 148.7, 148.2, 147.5, 147.4, 147.1, 147.1, 146.8, 146.1, 143.4, 143.3, 143.2, 143.1, 142.1, 141.3, 140.9, 139.8, 137.3, 134.3, 133.8, 131.5, 131.4, 131.2, 129.9, 129.8, 124.8, 117.5, 117.5, 66.6, 30.5, 19.2, 13.7. m/z (FD-MS) [M]⁺=1086.04, calculated for (C₈₄H₁₄O₄)=1086.09.

C70CP-PhBu2 (8b): Yield: 14%. ¹H-NMR (600 MHz, CDCl₃): δ 7.46-7.33 (m, 4H, —Ar—H), 7.29-7.06 (m, 6H, —Ar—H), 4.73-4.04 (m, 4H, C₃H₇—CH₂O—), 1.98-0.74 (m, 14H, CH₂ and CH₃). m/z (FD-MS) [M]⁺=1333.17, calculated for (C₉₈H₂₈O₈)=1332.18.

Fullerene derivative 9 was prepared by adapting above published procedure as follows: Dimethylaminopyridine (50 mg, 0.41 mmol) and PC₆₁BM (180 mg, 0.2 mmol) were dissolved in 50 mL dry toluene under argon. Dimethyl acetylenedicarboxylate (30 μL, 0.24 mmol) in 3 mL dry toluene was added dropwise and after stirring for 10 minutes methanol (150 μL, 3.7 mmol) was added dropwise. After stirring for another 30 minutes, the solution was heated to 60° C. for 2 hours. The solvent was removed under reduced pressure and the crude product was purified by column chromatography (Eluent: toluene/ethyl acetate) to give the product as a brown solid.

PC61BM-CP-MeMe1 (9): Yield: 40%. m/z (FD-MS) [M]⁺=1052.10, calculated for (C78H₂₀O₆)=1052.13.

IC60MA-CP-MeMe1 (10): Same procedure for compound 9 was used except IC60MA was used as starting material, and pure toluene was used as the eluent for column chromatography. Yield: 40%. m/z (FD-MS) [M]⁺=978.04, calculated for (C₇₅H₁₄O₄)=978.09.

### Example 2

### Characterization of the Thermal, Optical, Electrical, and Photovoltaic Properties of the Fullerene Derivatives (I)

The uniqueness of the synthesis and the properties of fullerene derivatives (I) and (II) include: (i) New chemistry which allows for straightforward synthesis, mild reaction condition, good yield and easy purification. Because these fullerenes have highly polar side groups including at least one carbonyl, one ether and one ester group, both mono and bis-fullerenes can be easily purified by short silica gel column chromatography. (ii) Convenience to tune product solubility. These derivatives can be tuned for their solubility in various solvents, such as but not limited to, chlorobenzene, 1,2-dichlorobenzene, chloroform, toluene, xylene, ethyl benzoate and tetralin, as demonstrated in table 1. (iii) Unique LUMO energy level. Data obtained from cyclic voltammetry indicated that both of the mono- and bis-addition fullerenes (I) have much lower LUMO level than that of commonly used fullerene derivatives such as PCBM or ICMA, and their LUMO levels are only slightly higher than pristine C₆₀ and C₇₀. This makes them more suitable to be combined with donor materials which have LUMO level too close to that of PCBM. The bis-addition fullerenes (II) have lower LUMO level than that of commonly used bis-fullerene derivatives such as bis-PCBM or ICBA, and their LUMO levels are only slightly higher than PCBM and ICMA. This makes them more suitable to be combined with donor materials which have LUMO level too close to that of bis-PCBM and ICBA, and suitable to be mixed with PCBM or ICMA to improve device morphological stability.

TABLE 1
Solubility of various fullerene derivatives (I) in chloroform.

| Fullerene name | Solubility in CHCl₃ (w/w %) |
|---|---|
| C60CP-PhMe1 | 0.6 |
| C60CP-PhMe2 | 2.2 |
| C60CP-PhBu1 | 3.4 |
| C60CP-PhBu2 | 4.4 |
| C70CP-PhBu1 | 4.5 |
| C70CP-PhBu2 | >8.4 |
| C60CP-MeMe1 | 0.7 |
| C60CP-MeMe2 | 1.0 |
| C60CP-BuBu1 | <0.1 |
| C60CP-BuBu2 | 3.9 |
| C60CP-F2PhMe1 | 0.6 |
| C60CP-F2PhMe2 | 3.4 |
| C60CP-F5PhMe1 | 0.4 |
| C60CP-F5PhMe2 | 0.3 |
| PC61BM-CP-MeMe1 | >5 |
| IC60MA-CP-MeMe1 | >2 |

Fullerene solubility is an important parameter which affects their processibility, device morphology and stability. Slight variations in the structure of a fullerene derivative can cause a significant change in its solubility in organic solvents. It has been shown that the best donor/acceptor combinations are those where donor and acceptor components are of similar and sufficiently high solubility in the solvent used for the deposition of the active layer [29]. Here chloroform was chosen as the solvent because it is a common solvent for solar cell fabrication and dissolves most of the existing semiconducting donor polymers. Various fullerene derivatives (I) and (II) with dramatically different solubility in chloroform were synthesized according to Scheme 1 following similar procedure. As demonstrated in Table 1, their solubility can be easily tuned from less than 0.1 wt % to more than 8 wt % or higher by changing the R¹ and R² groups.

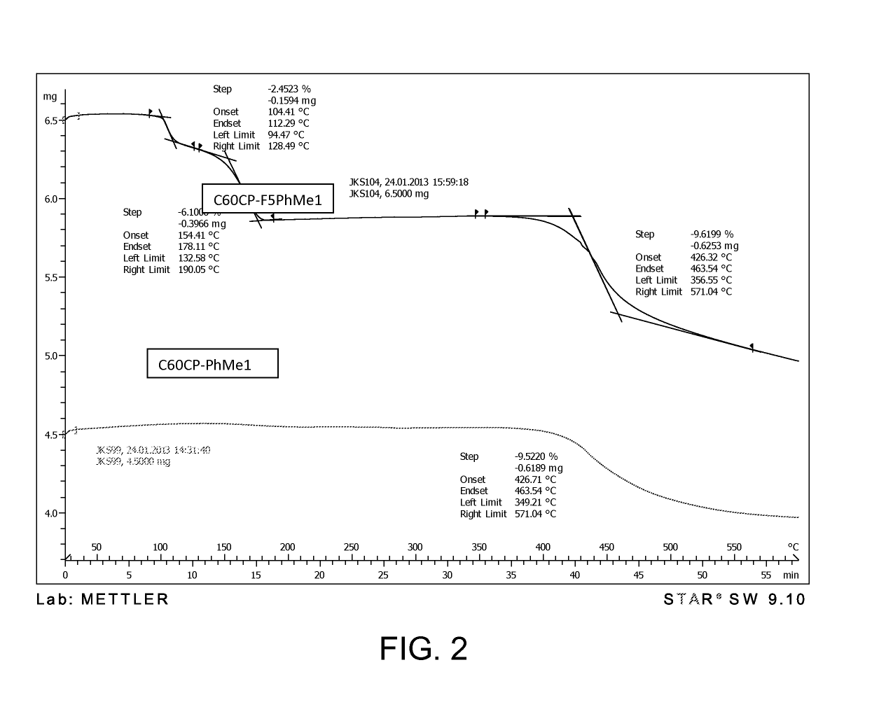

Good thermal stability is always required for any application including OPV, OTFT and OLED. Thermal property of selected fullerene derivatives (I) and (II) was measured using a METTLER TGA/sDTA851e Thermo Gravimetric Analyzer with a scan rate of 10° C./minutes under nitrogen flow. As shown in FIG. 2, no weight loss was observed for fullerene C60CP-PhMe1 up to 400° C., indicating excellent thermal stability. Small weight losses were observed from fullerene C60CP-F5PhMe1 around 100° C. and 150° C. which can be attributed to the loss of residue solvents.

The electronic property of the synthesized fullerenes are characterized by cyclic voltammetry (CV) using a Bio-Logic Multi-channel Potentiostat with Pt as a counter electrode, Ag/Ag+ as a reference electrode and ferrocene as an internal reference, with 4:1 v/v ratio of o-dichlorobenzene and acetonitrile as solvent and 0.1 M tetrabutylammonium hexafluorophosphate as electrolyte at a scan rate of 100 mV/s. The CV measurements showed that all the 1^{st}, 2^{nd}, and 3^{rd} reductions are reversible. The LUMO levels are calculated according to the following equation 2 using the onset of the first reduction. The data are listed in Table 2, LUMOs of C₆₀, C₇₀, PCBM, Bis-PCBM, ICMA and ICBA were measured under the same condition and listed too as reference.

E_{LUMO}=[(E_{FLN(Vs Ag/Ag+)}(E^{1/2}_{Ferrocene(Vs Ag/Ag+)}]−4.8 eV (equation 2)

TABLE 2
LUMO energy level of various fullerene derivatives (I) and (II)
measured by cyclic voltammetry.

| Fullerene name | LUMO Energy Level (eV) |
|---|---|
| C₆₀ | −3.90 |
| C₇₀ | −3.90 |
| PC₆₁BM | −3.80 |
| Bis-PC₆₁BM | −3.72 |
| IC₆₀MA | −3.76 |
| IC₆₀BA | −3.67 |
| C60CP-PhMe1 | −3.89 |
| C60CP-PhMe2 | −3.87 |
| C60CP-PhBu1 | −3.88 |
| C70CP-PhBu1 | −3.87 |
| C70CP-PhBu2 | −3.81 |
| C60CP-MeMe1 | −3.89 |
| C60CP-MeMe2 | −3.84 |
| C60CP-BuBu1 | −3.88 |
| C60CP-BuBu2 | −3.87 |
| C60CP-F2PhMe1 | −3.88 |
| C60CP-F2PhMe2 | −3.89 |
| C60CP-F5PhMe1 | −3.89 |
| C60CP-F5PhMe2 | −3.87 |
| C60CP-SPhMe1 | −3.86 |
| PC61BM-CP-MeMe1 | −3.77 |
| IC60MA-CP-MeMe1 | −3.75 |

In general, addition of carbon moieties to the fullerene cage leads to increased LUMO level, due to the loss of a double bond and reduction of the fullerene core conjugation, such as in the case of PCBM and ICMA, LUMO of both fullerenes increased about 0.1 eV compare to pristine C₆₀. Similarly, LUMO level of bis-addition fullerenes are higher than that of mono-addition fullerenes, such as LUMO of bis-PCBM and ICBA is about 0.1 eV and 0.15 eV higher than the LUMO of PCBM and ICMA respectively [15, 18]. However, the fullerene derivatives (I) and (II) of the present invention give very different LUMO energy levels. The mono-addition fullerene derivatives (I) show a LUMO level lower than that of PCBM and close to, mostly less than 0.5 eV difference with, the LUMO level of pristine C₆₀ and C₇₀, independent of the R¹ and R² substituents. More interestingly, the bis-addition derivatives (I) give almost the same LUMO levels as the mono-addition derivatives, which mean that the reduction of the number of fullerene double bonds does not lead to the rise of LUMO here. It is believed that this is due to the strong electron withdrawing effect of both the carbonyl group and the ester group, which almost perfectly offset the LUMO increase caused by the decrease of the number of the core double bonds, leading to almost zero shift of the LUMO orbital level. These fullerenes are particularly suitable to combine with donor materials which have very narrow bandgap and LUMO level close to that of PCBM. The bis-addition fullerene derivatives (II) showed much lower LUMO level than that of bis-PCBM and ICBA, but similar LUMO levels to, and less than 0.5 eV difference with, PCBM and ICMA, which make them suitable as PCBM and ICMA replacement, or to be mixed with PCBM or ICMA to improve device morphological stability.

Photovoltaic properties of the fullerene derivatives (I) and (II) are evaluated using either a conventional device structure ITO/PEDOT:PSS/polymer:fullerene/Ca/Al or an inverted device structure ITO/ZnO₂/polymer: fullerene/MoO₃/Ag. The general procedure to fabricate conventional bulk heterojunction polymer:fullerene devices is as following: ITO substrates were sonicated for 20 minutes each in soap water, deionized water, acetone, and isopropanol and kept in isopropanol until use. PEDOT:PSS (Clevios P VP A14083) was filtrated with a 0.45 μm PTFE filter and spin-coated onto ITO substrate with a spin rate of 4000 rpm/s and spin time of 45 s, then baked on a hotplate at 120° C. for 10 minutes, transferred to glove box immediately. PEDOT:PSS coated ITO substrates were baked again at 195° C. for 3 minutes before use. Polymer: fullerene (FLN) solutions dissolved in 1 ml of o-dichlorobenzene (ODCB) or chlorobenzene (CB) at 80° C. were filtered with a 0.45 μm PTFE filter and spin-coated onto the ITO substrate at a desired spin rate. The films may be further annealed at different conditions to optimize the device performance. Then Ca (20 nm)/A1 (80 nm) were thermally evaporated as the cathode at a pressure of ˜10⁻⁷ torr, using a shadow mask with an active area of ˜6 mm².

The general procedure to fabricate inverted bulk heterojunction polymer:fullerene devices is as following: ITO substrates were sonicated for 20 minutes each in soap water, deionized water, acetone, and isopropanol and kept in isopropanol until use. The ZnO precursor was prepared by dissolving zinc acetate dihydrate (Zn(CH₃COO)₂.2H₂O, 1 g) and ethanolamine (NH₂CH₂CH₂OH, 0.28 g) in 2-methoxyethanol (CH₃OCH₂CH₂OH, 10 mL) under vigorous stirring for 12 h for the hydrolysis reaction in air. The ZnO precursor solution was spin-cast on top of the ITO-glass substrate and annealed at 200° C. for 1 hour in air, then the ZnO-coated substrates were transferred into a glove box. Polymer: fullerene (FLN) solutions dissolved in 1 ml of o-dichlorobenzene (ODCB) or chlorobenzene (CB) at 80° C. were filtered with a 0.45 μm PTFE filter and spin-coated onto the ITO substrate at a desired spin rate. The films may be further annealed at different conditions to optimize the device performance. Then a thin layer of MoO₃ film (6 nm) was evaporated on top of the active layer. Finally, the anode (Ag, ≈60 nm) was deposited through a shadow mask by thermal evaporation in a vacuum of about 3×10⁻⁶ Torr.

The J-V characteristics were measured at 1 sun (AM 1.5G) in a N₂-filled glovebox equipped with a Xenon lamp (Newport) and Keithley 2408 SMU. Each parameter is averaged from over 5 devices fabricated and tested under the same condition. The errors are given in the table too. Control devices with PCBM as the acceptor were fabricated under the same conditions to compare. Power conversion efficiency 11 is calculated by the following equation 1:

PCE(%)=(V_{oc})(J_{sc})(ff/P_{inc}) (equation 1)

Where V_{oc} is the open circuit voltage (V) which is the device voltage when no external electric current flows between the terminals; J_{sc} is the short circuit current density (mA/cm²) which is the current of the solar cell when the voltage across the solar cell is zero (i.e., when the solar cell is short circuited); ff is fill factor which is the ratio of maximum obtainable power to the product of the open-circuit voltage and short-circuit current; P_{inc} is the intensity of incident light (mW/cm²).

First, regioregular poly(3-hexyl)thiophene (P3HT, E_{LUMO}˜−3.2 eV) is used as the donor polymer to screen these fullerene derivatives, the P3HT to mono-fullerene ratio of 1:0.9 was used and ODCB was used as the solvent. Devices were either solvent annealed under a petri dish or thermally annealed at different temperatures. The average J_{sc}, V_{oc}, ff and power conversion efficiency for each fullerene were summarized in Table 3. All the mono fullerene devices showed about 0.03-0.13 eV lower V_{oc} compare to devices with PCBM as acceptor, which is in good agreement with their lower LUMO levels. It is important to point out that the device current densities and fill factors are comparable with devices with PCBM as acceptor, which indicates that the active layers still maintained good morphology and electron mobility.

TABLE 3
Summary of solar cell device performance with fullerene derivatives
(I) as acceptor and P3HT as donor.

| | V_{oc} (V) | Jsc (mA/cm²) | ff | η(%) |
|---|---|---|---|---|
| P3HT_PCBM | 0.62 ± 0.004 | 9.74 ± 0.26 | 0.67 ± 0.01 | 4.04 ± 0.16 |
| P3HT_C60CP- | 0.55 ± 0.004 | 8.49 ± 0.19 | 0.68 ± 0.01 | 3.16 ± 0.10 |
| PhMe1 | | | | |
| P3HT_C60CP- | 0.57 ± 0.003 | 8.70 ± 0.12 | 0.68 ± 0.003 | 3.37 ± 0.07 |
| PhBu1 | | | | |
| P3HT_C60CP- | 0.63 ± 0.002 | 7.00 ± 0.02 | 0.47 ± 0.01 | 2.08 ± 0.06 |
| PhBu2 | | | | |
| P3HT_C60CP- | 0.49 ± 0.002 | 8.56 ± 0.04 | 0.65 ± 0.004 | 2.72 ± 0.04 |
| F2PhMe1 | | | | |
| P3HT_C60CP- | 0.54 ± 0.01 | 6.51 ± 0.31 | 0.64 ± 0.02 | 2.26 ± 0.06 |
| F5PhMe1 | | | | |
| P3HT_C60CP- | 0.56 ± 0.002 | 5.79 ± 0.07 | 0.62 ± 0.001 | 2.00 ± 0.01 |
| MeMe1 | | | | |
| P3HT_C60CP- | 0.59 ± 0.01 | 9.25 ± 0.40 | 0.58 ± 0.03 | 3.17 ± 0.29 |
| BuBu1 | | | | |
| P3HT_C60CP- | 0.68 ± 0.003 | 8.10 ± 0.13 | 0.55 ± 0.01 | 3.01 ± 0.04 |
| BuBu2 | | | | |
| P3HT_C60CP- | 0.53 ± 0.01 | 3.94 ± 0.23 | 0.51 ± 0.01 | 1.07 ± 0.10 |
| SPhMe1 | | | | |
| P3HT_PC61BM- | 0.65 ± 0.01 | 8.24 ± 0.14 | 0.65 ± 0.03 | 3.47 ± 0.12 |
| CP-MeMe1 | | | | |
| P3HT_IC60MA- | 0.72 ± 0.01 | 8.42 ± 0.17 | 0.65 ± 0.02 | 3.89 ± 0.07 |
| CP-MeMe1 | | | | |

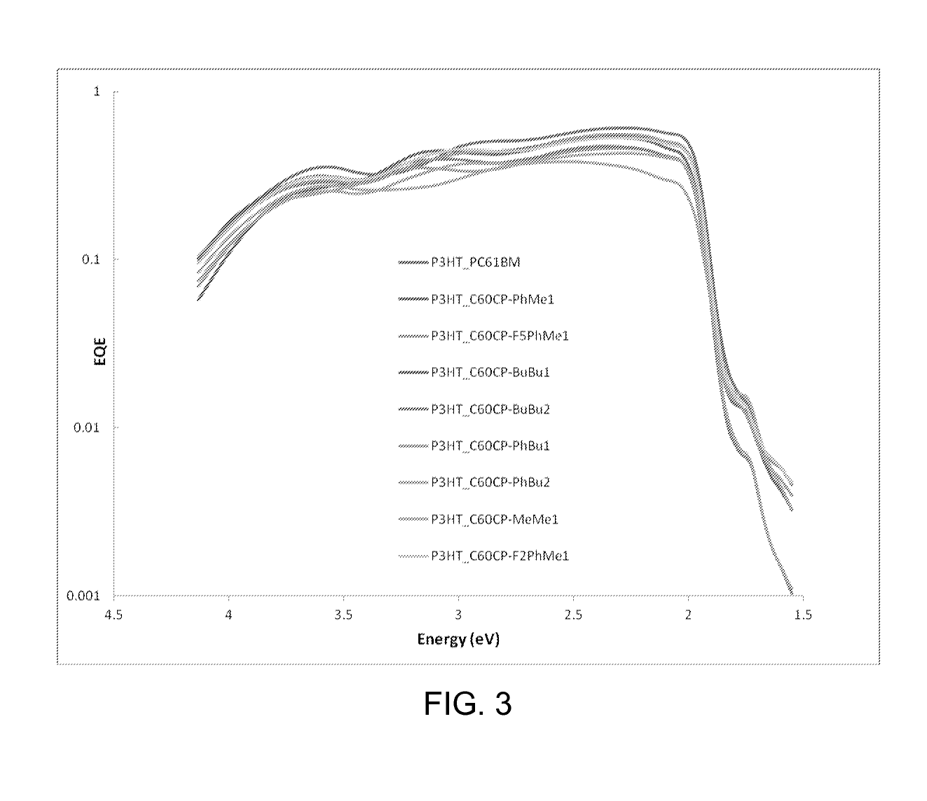

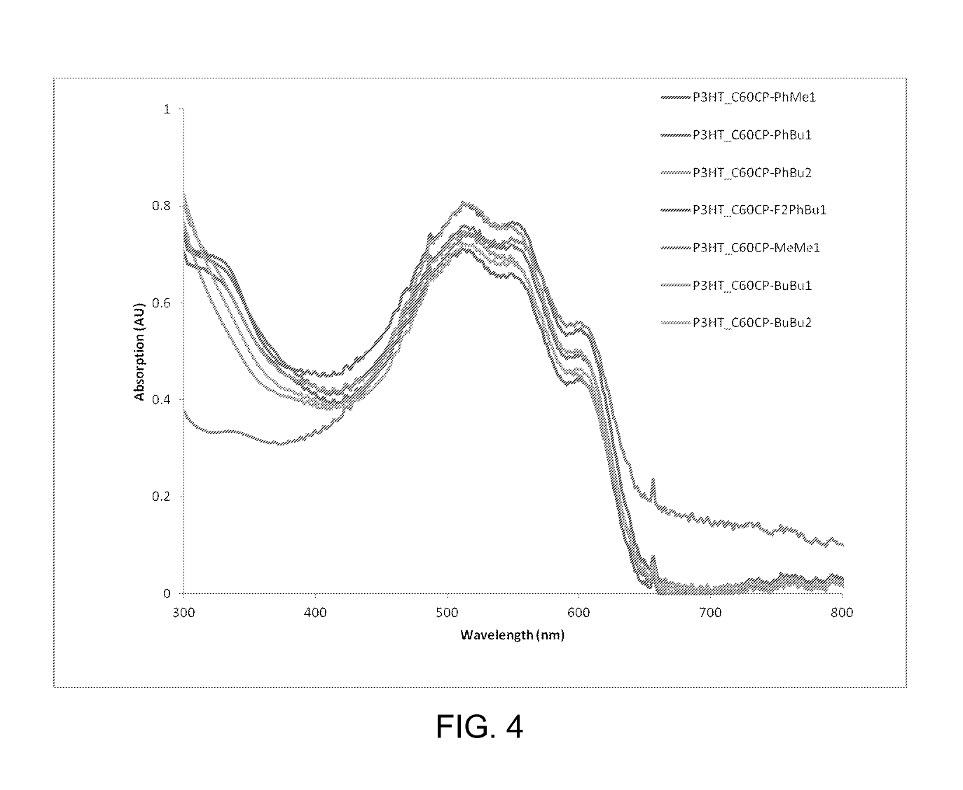

When bis-fullerenes are used as acceptor, P3HT to fullerene ratio of 1:1.1 is used and the devices showed comparable current densities and fill factors with devices using PCBM as acceptor. Interestingly, device V_{oc} are sometimes higher or much higher than V_{oc} of devices with PCBM as acceptor, even the LUMOs of the bis-fullerenes are lower than or close to the LUMO of PCBM. It is suspected that this is caused by the different morphology as evidenced by their EQE profiles (FIG. 3). It can be easily seen in FIG. 3 that all the devices with mono-fullerenes as acceptor showed very similar behavior at P3HT and fullerene bulk and sub-bandgap absorption regions. However, devices with bis-fullerenes as acceptor gave much lower EQE at sub-bandgap absorption region, even the bulk absorption in all the devices are very similar (FIG. 4, the derivation from device with C60CP-MeMe1 as acceptor is caused by the light scattering from excessive crystallization of C60CP-MeMe1 in the film). It has been shown that V_{oc} of bulk heterojunction solar cells is determined by the interfacial charge-transfer CT states between donor and acceptor, so as to the recombination at the interface [30-34]. The much lower sub-bandgap EQE here is an indication of less donor/acceptor interfacial area, sharper interface, or different donor/acceptor conformation, thus less charge transfer states. Charge transfer states occur due to electronic overlap at interfaces of donors and acceptors and are the sites of recombination in OPVs. Likely the higher V_{oc} from devices with bis-fullerenes as acceptor is a result of less recombination.

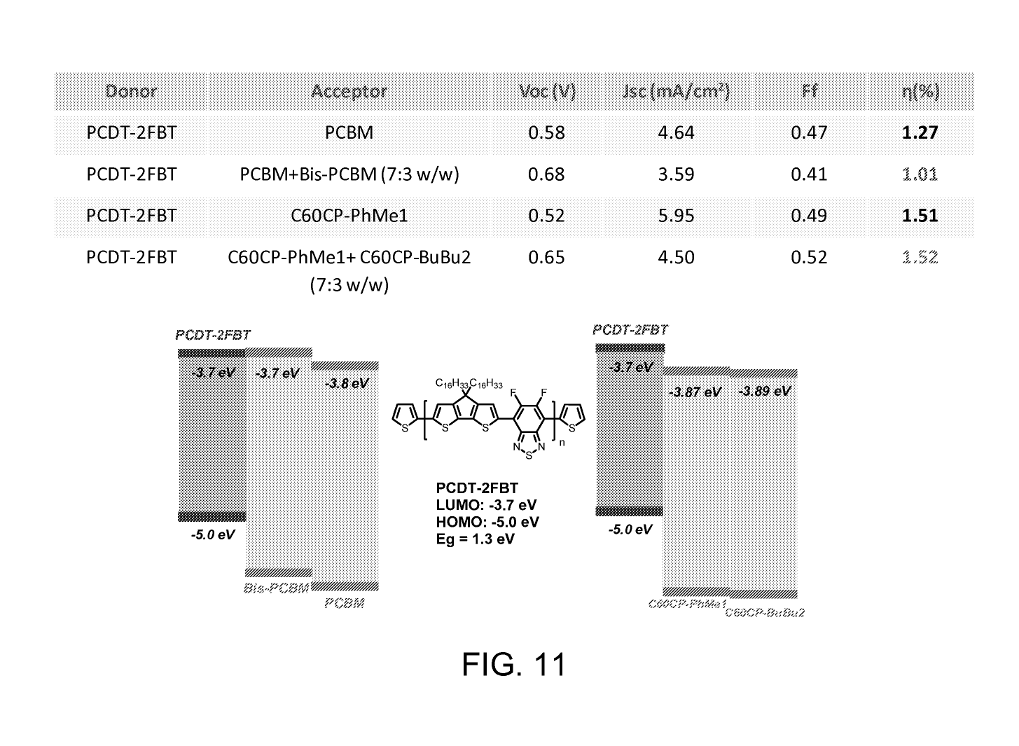

When combining with high LUMO donor materials such as P3HT or a donor with higher LUMO than P3HT, devices with fullerene derivatives (I) and (II) showed no improvement over PCBM, because there's already enough driving force for charge separation between P3HT and PCBM. To demonstrate the advantage of these fullerenes, a low LUMO donor polymer PCDT-2FBT is selected (see below and FIG. 11).

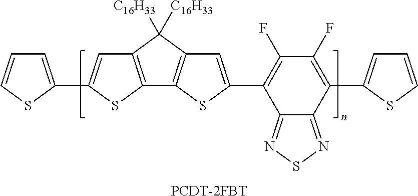

This donor polymer has a very narrow bandgap of 1.3 eV and low LUMO of −3.69 eV as measured by UV-vis absorption spectroscopy and Photo Yield Spectroscopy (PYS) respectively. Because its LUMO is only 0.11 eV higher than the LUMO of PCBM, when PCBM is used as the acceptor in the solar cell device, low device current density of 4.64 mA/cm² was achieved with a device efficiency of 1.27%, likely due to the inefficient charge separation between PCDT-2FBT and PCBM. When C60CP-PhMe1 was used as the acceptor, device V_{oc} dropped 0.06 eV due to the lower LUMO of C60CP-PhMe1, but device current density dramatically increased to 5.95 mA/cm² and device ff increased slightly too, which resulted in an overall 20% device efficiency increase to 1.51%. This demonstrated that these fullerene derivatives (I) could be a better choice of acceptor for organic solar cells with narrow bandgap, low LUMO donor materials. The average J_{sc}, V_{oc}, ff and power conversion efficiency is summarized in Table 4 below.

TABLE 4
Device performance with single or mixture of mono and bis-fullerenes as acceptor
and PCDT-2FBT as donor.

| Donor | Acceptor | Voc (V) | Jsc (mA/cm²) | Ff | η(%) |
|---|---|---|---|---|---|
| PCDT-2FBT | PCBM | 0.58 ± 0.001 | 4.64 ± 0.12 | 0.47 ± 0.003 | 1.27 ± 0.03 |
| PCDT-2FBT | PCBM + Bis-PCBM (7:3 w/w) | 0.68 ± 0.005 | 3.59 ± 0.15 | 0.41 ± 0.004 | 1.01 ± 0.04 |
| PCDT-2FBT | C60CP-PhMe1 | 0.52 ± 0.02 | 5.95 ± 0.15 | 0.49 ± 0.01 | 1.51 ± 0.08 |
| PCDT-2FBT | C60CP-PhMe1 + C60CP- | 0.65 ± 0.01 | 4.50 ± 0.24 | 0.52 ± 0.01 | 1.52 ± 0.08 |
| | BuBu2 (7:3 w/w) | | | | |

High purity of fullerenes had been a requirement to achieve maximum device efficiency for organic solar cells. Using PCBM as an example, presence of impurities such as unreacted C₆₀ or bis-PCBM may lower the device efficiency dramatically. This is because the LUMO of C₆₀ is about 0.1 eV lower than LUMO of PCBM and the LUMO of bis-PCBM is 0.1 eV higher than that of PCBM. As a result, they may lower the device V_{oc}, cause inefficient charge separation or act as charge traps that lower device current density. However, separation of side products and impurities during fullerene synthesis is often complicated and time-consuming. Chromatography with long silica gel columns is commonly used for the purification of PCBM and bis-PCBM, high pressure liquid chromatography (HPLC) or gel permeation chromatography (GPC) is needed for the purification of ICMA and ICBA. This greatly limited the production capability of these fullerenes and result in very high production cost. For example, the price of C₆₀ (1 g, 99.5% purity) is $45, but the price of PC₆₁BM (1 g, 99.5% purity) increased almost 20 times to $875. In the case of fullerene derivatives (I), because both the mono and bis-fullerenes have very close LUMO levels with pristine fullerene, it is expected that the mixture of pristine fullerene, mono-fullerene and bis-fullerene may be used as the acceptor without dramatically affecting the solar cell performance. This is confirmed by examples below.

With P3HT as donor polymer, the mixture of PCBM and C₆₀ and the mixture of C60CP-PhBu1 and C₆₀ in 7:3 w/w ratio were tested as acceptors. As listed in Table 4, when a mixture of PCBM and C₆₀ was used as the acceptor, device V_{oc} showed a dramatic drop from 0.62 eV to 0.57 eV due to the lower LUMO of C₆₀. However, when a mixture of C60CP-PhBu1 and C₆₀ is used as the acceptor, device V_{oc} has almost no change, because C60CP-PhBu1 has a LUMO very close to that of C₆₀. In both cases, device J_{sc} increased but ff dropped when a mixture is used as acceptor. Overall, device efficiency with PCBM/C₆₀ mixture as acceptor dropped 12% compared to device with only PCBM as acceptor, but device efficiency with C60CP-PhBu1 and C₆₀ mixture as acceptor only dropped 4% compared to device with only C60CP-PhBu1 as acceptor (Table 5). This confirmed that the fullerene derivatives (I) have a much higher tolerance to the existence of pristine fullerene due to their close LUMO levels.

TABLE 5
Device performance with single or mixture of pristine and mono-fullerenes as
acceptorand P3HT as donor.

| Donor | Acceptor | Voc (V) | Jsc (mA/cm²) | ff | η(%) |
|---|---|---|---|---|---|
| P3HT | PCBM | 0.62 ± 0.004 | 9.74 ± 0.26 | 0.67 ± 0.01 | 4.04 ± 0.16 |
| P3HT | PCBM + C₆₀ (7:3 w/w) | 0.57 ± 0.002 | 10.1 ± 0.13 | 0.62 ± 0.01 | 3.56 ± 0.08 |
| P3HT | C60CP-PhBu1 | 0.55 ± 0.004 | 8.90 ± 0.38 | 0.63 ± 0.01 | 3.08 ± 0.13 |
| P3HT | C60CP-PhBu1 + C₆₀ (7:3 w/w) | 0.54 ± 0.003 | 10.2 ± 0.41 | 0.53 ± 0.02 | 2.95 ± 0.01 |

With a low LUMO copolymer PCDT-2FBT as donor polymer, the mixture of PCBM and bis-PCBM and the mixture of C60CP-PhMe1 and C60CP-BuBu2 in 7:3 w/w ratio were tested as acceptors. As listed in Table 4, in both cases, device V_{oc} increased which may be due to the higher device resistance or different device morphology. And in both cases, device J_{sc} dropped. But in the case of PCBM+bis-PCBM, device ff dropped too, which did not occur when a mixture of C60CP-PhMe1 and C60CP-BuBu2 was used as the acceptor. Overall, device efficiency with PCBM and bis-PCBM mixture as acceptor dropped about 25% compared to device with only PCBM as acceptor, but device efficiency with C60CP-PhMe1 and C60CP-BuBu2 mixture as acceptor slightly increased comparing to device with only C60CP-PhMe1 as acceptor. This confirmed that the mono fullerene derivatives (I) have a much higher tolerance to the presence of bis-fullerene due to their close LUMO levels.

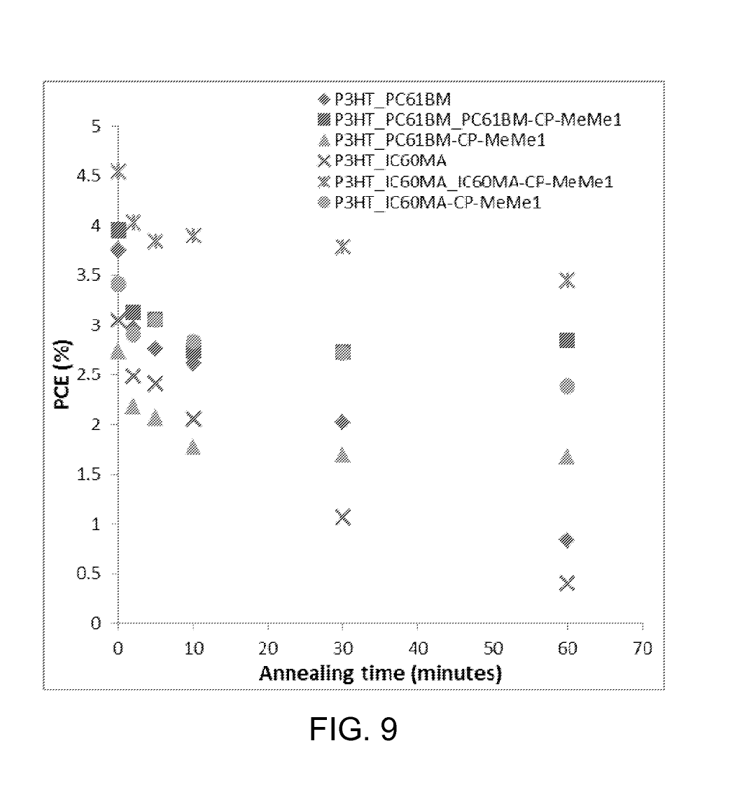

To test the effect of bis-fullerene derivatives on device thermal stability, PC₆₁BM, IC₆₀MA, PC61BM-CP-MeMe1, IC60MA-CP-MeMe1, the 1:1 (wt) mixture of PC₆₁BM and PC61BM-CP-MeMe1, and the 1:1 (wt) mixture of IC₆₀MA and IC60MA-CP-MeMe1 were used as acceptors, with P3HT as the donor polymer. The devices were solvent annealed first to reach optimized morphology and efficiency, then left on hotplate at 160° C. for 2 minutes, 5 minutes, 10 minutes, 30 minutes and an hour respectively before the evaporation of the top metal electrode. Device efficiencies after various annealing times are listed in Table 6, and trends of device efficiencies vs. annealing times are shown in FIG. 9.

The optimized device with the 1:1 (wt) mixture of PC₆₁BM and PC61BM-CP-MeMe1 as acceptor exhibits a power conversion efficiency 5% higher than a device with PC61BM as electron acceptor. The optimized device with the 1:1 (wt) mixture of IC₆₀MA and IC60MA-CP-MeMe1 as acceptor exhibits a power conversion efficiency 12% higher than a device with PC61BM as electron acceptor, 48% higher than a device with IC60MA as electron acceptor. This indicates that the mixed fullerenes which have LUMO levels within 0.05 eV of each other can provide superior device efficiency.

All the devices had an initial efficiency drop at the first 2 to 5 minutes of thermal annealing, which may due to the low Tg of P3HT. Efficiencies of devices with PC₆₁BM and IC₆₀MA as acceptor continuously dropped during annealing, until below 1% after one hour. However, efficiencies of devices with PC61BM-CP-MeMe1, IC60MA-CP-MeMe1, the mixture of PC₆₁BM and PC61BM-CP-MeMe1, and the mixture of IC₆₀MA and IC60MA-CP-MeMe1 as acceptors stabilized after 10 minutes of annealing, which indicating superior thermal stability of these devices. This was further confirmed by optical microscopic images of the annealed devices. During annealing, fullerene crystals with size up to tens of microns formed in P3HT-PC₆₁BM and P3HT-IC₆₀MA devices. This led to isolated fullerene domains and the reduction of interfacial density between the donor and the acceptor, resulting in decreased exciton dissociation, charge separation and transportation. On the contrary, devices based on PC₆₁BM-CP-MeMe1, IC₆₀MA-CP-MeMe1, the mixture of PC₆₁BM and PC₆₁BM-CP-MeMe1, and the mixture of IC₆₀MA and IC₆₀MA-CP-MeMe1 showed no sign of excessive fullerene aggregation after annealing for one hour at 160° C. This proved that not only devices based on the bis-fullerenes have higher device stability, but these bis-fullerenes can also stabilize mono-fullerenes like PCBM and ICMA, by slowing down or stop their crystallization process.

TABLE 6
PCE vs. annealing time of
various fullerene based devices.

| Thermal Annealing | | | | | | |
|---|---|---|---|---|---|---|
| time (minutes) | 0 | 2 | 5 | 10 | 30 | 60 |
| PCE(%) P3HT_PC61BM | 3.75 | 2.96 | 2.76 | 2.62 | 2.02 | 0.83 |
| PCE(%) P3HT_PC61BM_ | 3.95 | 3.12 | 3.06 | 2.74 | 2.73 | 2.84 |
| PC61BM-CP-MeMe1 | | | | | | |
| PCE(%) P3HT_PC61BM-CP- | 2.73 | 2.18 | 2.07 | 1.77 | 1.69 | 1.67 |
| MeMe1 | | | | | | |
| PCE(%) P3HT_IC60MA | 3.05 | 2.49 | 2.41 | 2.06 | 1.07 | 0.4 |
| PCE(%) P3HT_IC60MA_ | 4.54 | 4.03 | 3.84 | 3.9 | 3.79 | 3.45 |
| IC60MA-CP-MeMe1 | | | | | | |
| PCE(%) P3HT_IC60MA-CP- | 3.41 | 2.91 | 3.05 | 2.83 | 2.72 | 2.38 |
| MeMe1 | | | | | | |

In conclusion, embodiments of this invention include solar cell devices comprising an active layer comprising one or more fullerene derivatives as electron acceptor. The fullerene derivatives can be a pristine fullerene, or functionalized fullerene derivatives (I), or functionalized fullerene derivatives (II) incorporating a five membered cyclopentene ring as shown in Scheme 1 and 2. The fullerene derivatives have great commercial value as electron acceptor for organic or hybrid solar cells. They can be readily synthesized and purified by a one pot reaction with excellent yield. Their solubility can be readily tuned by changing R¹ and R² groups. They exhibit an LUMO energy level lower than that of PCBM or bis-PCBM, which makes them a better candidate when combing with narrow bandgap donor materials with a LUMO level lower than the LUMO of P3HT or no higher than 0.4 eV of the LUMO of PCBM. Furthermore, variation of type (X, R¹ and R² groups) and number of functional groups has little effect on the LUMO energy levels of these fullerene derivatives, which makes it possible to achieve excellent solar cell device efficiency and stability with low coat, mixed fullerenes.

Note: This application references a number of different publications as indicated throughout the specification by one or more reference numbers within brackets, e.g., [x]. A list of these different publications ordered according to these reference numbers can be found below in the section entitled “REFERENCES”. Each of these publications is incorporated by reference herein. All publications, patents, and patent applications cited herein are hereby incorporated by reference in their entirety for all purposes. Publications cited herein are cited for their disclosure prior to the filing date of the present application. Nothing here is to be construed as an admission that the inventors are not entitled to antedate the publications by virtue of an earlier priority date or prior date of invention. Further the actual publication dates may be different from those shown and require independent verification.

### REFERENCES

1. J. C. Hummelen, B. W. Knight, F. LePeq, F. Wudl, J. Yao, C. L. Wilkins, J. Org. Chem., 1995, 60, 532.
2. G. Yu, J. Gao, J. C. Hummelen, F. Wudl, A. J. Heeger, Science, 1995, 270, 1789.
3. W. Ma, C. Yang, X. Gong, K. Lee, A. J. Heeger, Adv. Funct. Mater. 2005, 15, 1617.
4. V. Shorotriya, J. Huang, Y. Yao, T. Moriarty, K. Emery, Y. Yang, Nat. Mater., 2005, 4, 864.
5. J. Peet, J. Y. Kim, N. E. Coats, W. L. Ma, D. Moses, A. J. Heeger, G. C. Bazan, Nature. Mater., 2007, 6, 497-500.
6. N. Blouin, A. Michaud, D. Gendron, S. Wakim, E. Blair, R. Neagu-Plesu, M. Belletête, G. Durocher, Ye Tao, M. Leclerc, J. Am. Chem. Soc., 2008, 130, 732-742.
7. Y. Liang, Y. Wu, D. Feng, S.-T. Tsai, H.-J. Son, G. Li, L. Yu, J. Am. Chem. Soc. 2009, 131, 56-57.
8. H.-Y. Chen, J. Hou, S. Zhang, Y. Liang, G. Yang, Y. Yang, L. Yu, Y. Wu, G. Li, Nature Photonics, 2009, 3, 649-653.
9. T.-Y. Chu, J. Lu, S. Beaupré, Y. Zhang, J.-R. Pouliot, S. Wakim, J. Zhou, M. Leclerc, Z. Li, J. Ding, Y. Tao, J. Am. Chem. Soc., 2011, 133, 4250-4253.
10. S. D. Dimitrov, A. A. Bakulin, C. B. Nielsen, B. C. Schroeder, J. Du, H. Bronstein, I. McCulloch, R. H. Friend, J. R. Durrant, J. Am. Chem. Soc. 2012, 134, 18189-18192.
11. Z. He, C. Zhong, S. Su, M. Xu, H. Wu, Y. Cao, Nature Photonics, 2012, 6, 591.
12. J. You, L. Dou, K. Yoshimura, T. Kato, K. Ohya, T. Moriarty, K. Emery, C.-C. Chen, J. Gao, G. Li, Y. Yang, Nature Commun., 2013, 1-10.
13. F. B. Kooistra, J. Knol, F. Kastenberg, L. M. Popescu, W. J. H. Verhees, J. M. Kroon, J. C. Hummelen, Org. Lett., 2007, 9, 551-554.
14. S. A. Backer, K. Sivula, D. F. Kavulak, J. M. J. Fréchet, Chem. Mater. 2007, 19, 2927-2929.
15. M. Lenes, G.-J. A. H. Wetzelaer, F. B. Kooistra, S. C. Veenstra, J. C. Hummelen, P. W. M. Blom, Adv. Mater. 2008, 20, 2116-2119.
16. Y. Matsuo, Y. Sato, T. Niinomi, I. Soga, H. Tanaka, E. Nakamura, J. Am. Chem. Soc. 2009, 131, 16048-16050.
17. D. W. Laird, R. Stegamat, M. Daadi, H. Richter, V. Vejins, L. Scott, T. A. Lada, US20100132782A1.
18. Y. He, H.-Y. Chen, J. Hou, and Y. Li, J. Am. Chem. Soc. 2010, 132, 1377-1382.
19. C.-Z. Li, S.-C. Chien, H.-L. Yip, C.-C. Chueh, F.-C. Chen, Y. Matsuo, E. Nakamura A. K.-Y. Jen, Chem. Commun., 2011, 47, 10082-10084.
20. C.-Z. Li, H.-L. Yip, A. K.-Y. Jen, J. Mater. Chem., 2012, 22, 4161-4177.
21. D. M. de Leeuw, M. M. J. Simenon, A. R. Brown, R. E. F. Einerhand, Synth. Metals, 1997, 87, 53-59.
22. M. C. Scharber, D. Mühlbacher, M. Koppe, P. Denk, C. Waldauf, A. J. Heeger, C. J. Brabec, Adv. Mater. 2006, 18, 789-794.
23. Y. Zhang, J. Zou, C.-C. Cheuh, H.-L. Yip, A. K.-Y. Jen, Macromolecules 2012, 45, 5427-5435.
24. S. Albrecht, S. Janietz, W. Schindler, J. Frisch, J. Kurpiers, J. Kniepert, S. Inal, P. Pingel, K. Fostiropoulos, N. Koch, D. Neher, J. Am. Chem. Soc., 2012, 134, 14932-14944.
25. W. Zhang, T. M. Swager, J. Am. Chem. Soc., 2007, 129, 7714-7715.
26. W. Zhang, J. K. Sprafke, M. Ma, E. Y. Tsui, S. A. Sydlik, G. C. Rutledge, T. M. Swager, J. Am. Chem. Soc., 2009, 131, 8446-8454.
27. T. M. Swager, W. Zhang, US 2008/0221240.
28. G. H. Jeffery, A. I. Vogel, J. Chem. Soc. 1948, 674-683.
29. P. A. Troshin, H. Hoppe, J. Renz, M. Egginger, J. Y. Mayorova, A. E. Goryachev, A. S. Peregudov, R. N. Lyubovskaya, G. Gobsch, N. S. Sariciftci, V. F. Razumov, Adv. Funct. Mater. 2009, 19, 779.
30. J. Nelson, J. Kirkpatrick, P. Ravirajan, Phys. Rev. B, 2004, 69, 035337.
31. K. Vandewal, K. Tvingstedt, A. Gadisa, O. Inganas, J. V. Manca, Nature Mater. 2009, 8, 904.
32. M. Presselt, M. Bä\hat{r}enklau, R. Rösch, W. J. D. Beenken, E. Runge, S. Shokhovets, H. Hoppe, and G. Gobsch, Appl. Phys. Lett., 2010, 97, 253302.
33. K. Vandewal, K. Tvingstedt, A. Gadisa, O. Inganäs, J. V. Manca, Phys. Rev. B, 2010, 81, 125204.
34. R. A. Street, K. W. Song, and J. E. Northrup, Phys. Rev. B, 2011, 83, 165207.
35. K. Sivula, Z. T. Ball, N. Watanabe and J. M. J. Frechet, Adv. Mater., 2006, 18, 206.
36. Y. J. Cheng, M. H. Liao, C. Y. Chang, W. S. Kao, C. E. Wu and C. S. Hsu, Chem. Mater., 2011, 23, 4056.
37. X. Meng, W. Zhang, Z. Tan, C. Du, C. Li, Z. Bo, Y. Li, X. Yang, M. Zhen, F. Jiang, J. Zheng, T. Wang, L. Jiang, C. Shu and C. Wang, Chem. Commun., 2012, 48, 425.
38. M. Hashiguchi, N. Obata, M. Maruyama, K. S. Yeo, T. Ueno, T. Ikebe, I. Takahashi, Y. Matsuo, Org. Lett. 14 (2012) 3276-3279.
39. M. Koppe, U.S. Pat. No. 7,825,326.
40. D. F. Kronholm, J. C. Hummelen, A. B. Sieval, T. H. Patrick Van, PCT publication WO 2008/006071.
41. D. Laird, H. Richter, V. Vejins, L. Scott, T. Lada, PCT publication WO 2009/086210.
42. X. Wang, E. Perzon, J. L. Delgado, P. de la Cruz, F. Zhang, F. Langa, M. Andersson, O. Inganäs, Appl. Phys. Lett., 2004, 85, 5081-5083.
43. M. Prato, V. Lucchini, M. Maggini, E. Stimpf, G. Scorrano, M. Eiermann, T. Suzuki, F. Wudl. J. Am. Chem. Soc., 1993, 115, 8479-8480.
44. C. Bingel. Chemische Berichte 1993, 126, 1957-1959.
45. M. Maggini, G. Scorrano, M. Prato. J. Am. Chem. Soc., 1993, 115, 9798-9799.
46. M. Prato, Q. Chan Li, F. Wudl, V. Lucchini J Am. Chem. Soc., 1993, 115 (3), 1148-1150.
47. T. Suzuki, Q. Li, K. C. Khemani, and F. Wudl. J. Am. Chem. Soc., 1992, 114, 7301-7302.
48. Y. He, H.-Y. Chen, J. Hou, Y. Li. J. Am. Chem. Soc. 2010, 132, 1377-1382.
49. Y. Matsuo, A. Iwashita, Y. Abe, C.-Z. Li, K. Matsuo, M. Hashiguchi, E. Nakamura. J. Am. Chem. Soc. 2008, 130, 15429-15436.
50. J. K. Lee, W. L. Ma, C. J. Brabec, J. Yuen, J. S. Moon, J. Y. Kim, K. Lee, G. C. Bazan, A. J. Heeger, J. Am. Chem. Soc., 2008, 130, 3619-3623.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching.

1. A photovoltaic cell device including an active layer comprising at least one of:
an electron donor; and
an electron acceptor comprising a fullerene having the formula: 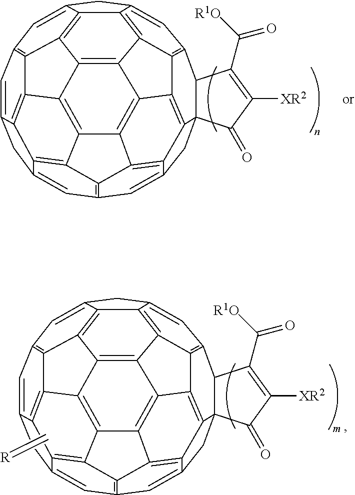
wherein:
the fullerene core exhibits the formula C₂ₙ;
X is selected from the group consisting of nitrogen, oxygen, and sulfur;
R¹ and R² are independently selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20;
a carbonyl, carboxylate, nitro, sulfonyl, amino, amide, cyano, hydroxyl, thiol, silyl, siloxy or halogen group; and
combinations of said R¹ and R² groups;
m is equal to 1 or 2;
n is equal to 1, 2 or 3; and
R is selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20; and
a carbonyl, carboxylate, nitro, sulfonyl, amino, amide, cyano, hydroxyl, thiol, silyl, siloxy or halogen group;
wherein the electron acceptor has a LUMO energy level lower than that of [6,6]-phenyl-C₆₁-butyric acid methyl ester (PCBM) or bis(1-[3-(methoxycarbonyl)propyl]-1-phenyl)[6,6]C₆₂ (bis-PCBM).

2. The device of claim 1, wherein R is a functional group selected from the group consisting of:

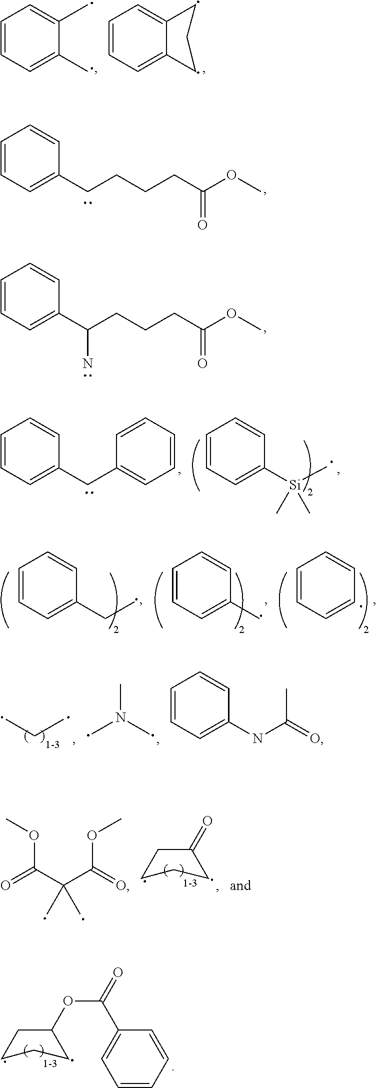

3. The device of claim 1, wherein the electron acceptor comprises at least 2 covalent bonds between the fullerene core and R, the at least 2 covalent bonds being bound to different carbons in the fullerene core.

4. The device of claim 3, wherein the at least 2 covalent bonds are bound to 1,2-carbons or 1,4-carbons of a six-member ring in the fullerene core.

5. The device of claim 1, wherein the electron donor is selected to have a LUMO level not more than 0.4 eV higher than the LUMO level of [6,6]-phenyl-C₆₁-butyric acid methyl ester (PCBM) or bis(1-[3-(methoxycarbonyl)propyl]-1-phenyl)[6,6]C₆₂ (bis-PCBM).

6. The device of claim 1, wherein the electron donor has a LUMO level at least 0.1 eV, 0.2 eV, 0.3 eV, 0.4 eV or 0.5 eV lower than the LUMO level of regioregular poly(3-hexylthiophene) (rr-P3HT).

7. The device of claim 1, wherein the electron acceptor is selected to have a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of bis-PCBM.

8. The device of claim 1, wherein the electron acceptor is selected to have a LUMO energy level at least 0.01 eV, 0.02 eV, 0.03 eV, 0.04 eV, 0.05 eV, 0.06 eV, 0.07 eV, 0.08 eV, 0.09 eV, 0.10 eV, 0.11 eV, 0.12 eV, 0.13 eV, 0.14 eV or 0.15 eV lower than that of PCBM.

9. The device of claim 1, wherein the device exhibits a power conversion efficiency at least 5% higher than a power conversion efficiency of an identical device with the same structure but with PCBM as an electron acceptor.

10. The device of claim 1, wherein the electron acceptor comprises a mixture of different fullerenes, the mixture of different fullerenes comprising at least one of:
(a) a mono-fullerene;
(b) a bis-fullerene;
(c) a tris fullerene; or
(d) a pristine fullerene;
wherein the mixture of different fullerenes comprises at least two compounds selected to have LUMO levels within 0.05 eV of each other.

11. The device of claim 10, wherein the mixture of different fullerenes comprises at least one of a compound having the formula: 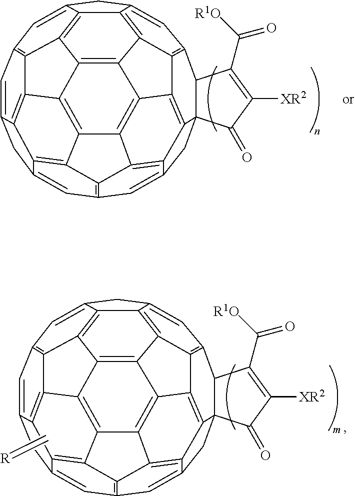
wherein:
the fullerene core exhibits the formula C₂ₙ;
X is selected from the group consisting of nitrogen, oxygen, and sulfur;
R, R¹, and R² are independently selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20;
a carbonyl, carboxylate, nitro, sulfonyl, amino, amide, cyano, hydroxyl, thiol, silyl, siloxy or halogen group; and
combinations of said R¹ and R² groups;
m is equal to 1 or 2;
n is equal to 1, 2 or 3;
wherein the loading of the fullerene is from 0.5 wt % to 100 wt %.

12. The device of claim 10, wherein the mixture of different fullerenes comprises at least one of a compound having the formula: 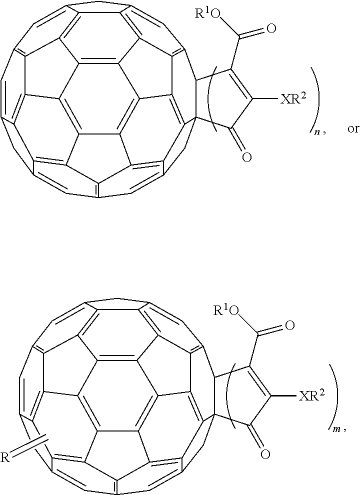
wherein:
the fullerene core exhibits the formula C₂ₙ;
X is selected from the group consisting of nitrogen, oxygen, and sulfur;
R, R¹ and R² are independently selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20;
a carbonyl, carboxylate, nitro, sulfonyl, amino, amide, cyano, hydroxyl, thiol, silyl, siloxy or halogen group; and
combinations of said R¹ and R² groups;
m is equal to 1 or 2;
n is equal to 2 or 3;
wherein the device exhibits a power conversion efficiency at least 5% higher than a power conversion efficiency of an identical device with the same structure but with PCBM as an electron acceptor.

13. The device of claim 10, wherein the mixture of different fullerenes comprises at least one of a compound having the formula: 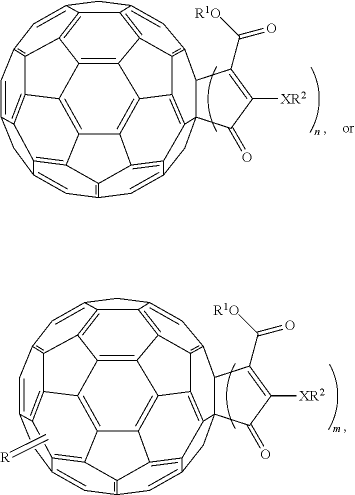
wherein:
the fullerene core exhibits the formula C₂ₙ;
X is selected from the group consisting of nitrogen, oxygen, and sulfur;
R, R¹, and R² are independently selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20;
a carbonyl, carboxylate, nitro, sulfonyl, amino, amide, cyano, hydroxyl, thiol, silyl, siloxy or halogen group; and
combinations of said R¹ and R² groups;
m is equal to 1 or 2;
n is equal to 2 or 3;
wherein the active layer comprises an original power conversion efficiency, and thermally annealing the active layer at 160° C. for one hour results in a power conversion efficiency of at least 60% of the original power conversion efficiency.

14. The device of claim 10, wherein thermally annealing the active layer at 160° C. for one hour results in a device with a power conversion efficiency that is at least 5% higher than that of an identical device with the same structure but with PCBM as an electron acceptor.

15. The device of claim 10, wherein thermally annealing the active layer at 160° C. for one hour results in a device with a power conversion efficiency that is at least 2 times higher than that of an identical device with the same structure but with PCBM as an electron acceptor.

16. The device of claim 10, wherein the mixture of different fullerenes comprises at least one of a compound having the formula: 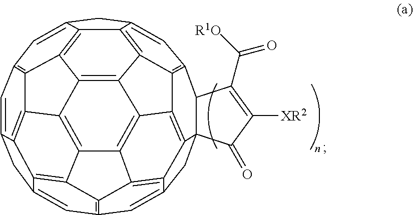
wherein C₆₀, R¹=Me, R²=Ph, X═O, n=1; C₆₀, R¹=Me, R²=Ph, X═O, n=2; C₆₀, R¹=Me, R²=Me, X═O, n=1; C₆₀, R¹=Me, R²=Me, X═O, n=2; C₆₀, R¹=Me, R²═F₂Ph, X═O, n=1; C₆₀, R¹=Me, R²═F₂Ph, X═O, n=2; C₆₀, R¹=Me, R²═F₅Ph, X═O, n=1; C₆₀, R¹=Me, R²═F₅Ph, X═O, n=2; C₆₀, R¹=Me, R²=Ph, X═S, n=1; C₆₀, R¹=n-Bu, R²=Ph, X═O, n=1; C₆₀, R¹=n-Bu, R²=Ph, X═O, n=2; C₆₀, R¹=n-Bu, R²=n-Bu, X═O, n=1; C₆₀, R¹=n-Bu, R²=n-Bu, X═O, n=2; C₇₀, R¹=n-Bu, R²=Ph, X═O, n=1; or C₇₀, R¹=n-Bu, R²=Ph, X═O, n=2; or 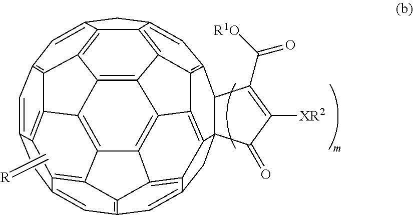
wherein R═ 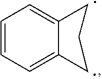
R¹═R²=Me or R═ 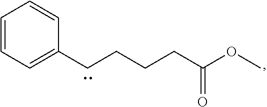
R¹═R²=Me, m is equal to 1 or 2.

17. The device of claim 10, wherein the device comprises:
a first electrode;
a second electrode; and
an active layer disposed between the first and second electrodes, wherein the active layer comprises a mono-fullerene and a bis-fullerene.

18. A method of forming an organic photovoltaic cell, wherein the method comprises:
forming an active layer composition including an electron donor and an electron acceptor, wherein the electron acceptor is selected to comprise:
a functionalized fullerene having the formula: 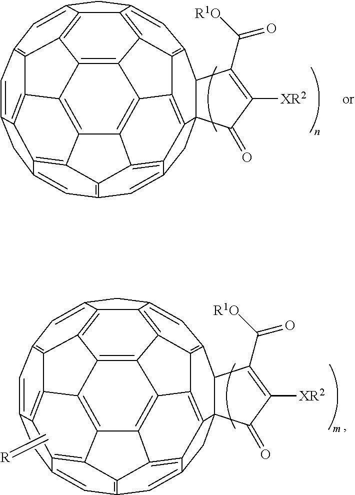
wherein:
the fullerene core exhibits the formula C₂ₙ;
X is selected from the group consisting of nitrogen, oxygen, and sulfur;
R¹ and R² are independently selected from the group consisting of:
hydrogen;
a Cₙ alkyl group, alkenyl group or alkynyl group, wherein n=1 to 30;
a Cₙ aryl group, wherein n=4 to 30;
a Cₙ heteroaryl group, wherein n=2 to 30;
a Cₙ fluoroalkyl group, wherein n=1 to 30;
a Cₙ fluoroaryl group, wherein n=2 to 30;
(CH₂CH₂O)ₙ, wherein n=1 to 20; and
a carbonyl, carboxylate, nitro, sulfonyl, amino, amide, cyano, hydroxyl, thiol, silyl, siloxy or halogen group; and
combinations of said R¹ and R² groups;
m is equal to 1 or 2;
n is equal to 1, 2 or 3; and
R is a functional group selected from the group consisting of: 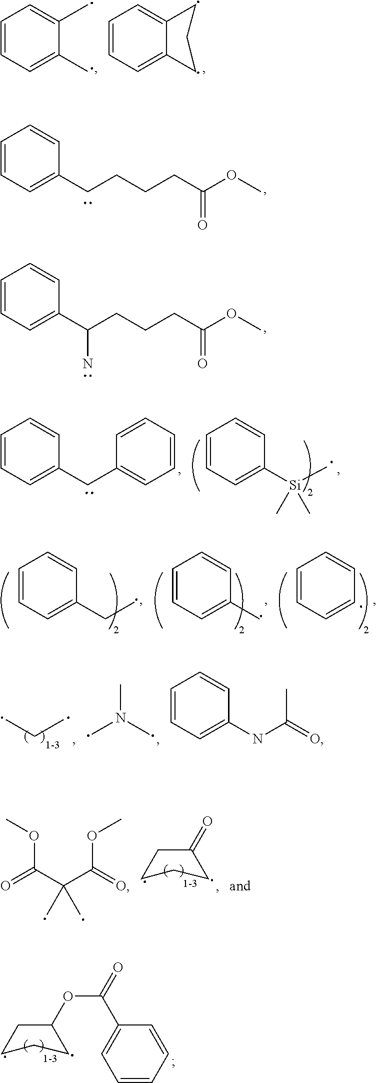
wherein the fullerene selected to exhibit a LUMO energy level lower than that of [6,6]-phenyl-C₆₁-butyric acid methyl ester (PCBM) or bis(1-[3-(methoxycarbonyl)propyl]-1-phenyl)[6,6]C₆₂ (bis-PCBM).

19. The method of claim 18, wherein C₆₀, R¹=Me, R²=Ph, X═O, n=1; C₆₀, R¹=Me, R²=Ph, X═O, n=2; C₆₀, R¹=Me, R²=Me, X═O, n=1; C₆₀, R¹=Me, R²=Me, X═O, n=2; C₆₀, R¹=Me, R²═F₂Ph, X═O, n=1; C₆₀, R¹=Me, R²═F₂Ph, X═O, n=2; C₆₀, R¹=Me, R²═F₅Ph, X═O, n=1; C₆₀, R¹=Me, R²═F₅Ph, X═O, n=2; C₆₀, R¹=Me, R²=Ph, X═S, n=1; C₆₀, R¹=n-Bu, R²=Ph, X═O, n=1; C₆₀, R¹=n-Bu, R²=Ph, X═O, n=2; C₆₀, R¹=n-Bu, R²=n-Bu, X═O, n=1; C₆₀, R¹=n-Bu, R²=n-Bu, X═O, n=2; C₇₀, R¹=n-Bu, R²=Ph, X═O, n=1; C₇₀, R¹=n-Bu, R²=Ph, X═O, n=2; R═ 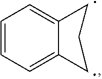
R¹═R²=Me; or R═ 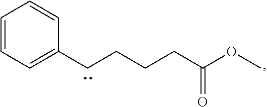
R¹═R²=Me.

20. The method of claim 18, wherein:
the electron donor is selected to exhibit a LUMO level not more than 0.40 eV, 0.35 eV, 0.30 eV, 0.25 eV, 0.2 eV, 0.15 eV, 0.1 eV or 0.05 eV higher than the LUMO level of PCBM or bis-PCBM; and/or
the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than that of PCBM or bis-PCBM.

21. The method of claim 18, wherein:
the electron donor is selected to exhibit a LUMO level not more than 0.40 eV, 0.35 eV, 0.30 eV, 0.25 eV, 0.2 eV, 0.15 eV, 0.1 eV or 0.05 eV higher than about −3.8 eV; and/or
the electron acceptor comprises at least one fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than about −3.8 eV.

22. The method of claim 18, wherein:
the electron donor is selected to exhibit a LUMO level not more than 0.40 eV, 0.35 eV, 0.30 eV, 0.25 eV, 0.2 eV, 0.15 eV, 0.1 eV or 0.05 eV higher than about −3.72 eV; and/or
the electron acceptor comprises at least one bis-fullerene selected to exhibit a LUMO energy level at least 0.01 eV, 0.02 eV, 0.03 eV, 0.04 eV, 0.05 eV, 0.06 eV, 0.07 eV, 0.08 eV, 0.09 eV, or 0.10 eV lower than about −3.72 eV.

23. The method of claim 18, wherein the electron donor is selected to exhibit a LUMO level not less than 0.1 eV lower than the LUMO level of regioregular poly(3-hexylthiophene) (rr-P3HT).

24. The method of claim 18, wherein the electron donor compound and the electron acceptor compound are selected to exhibit compatible solubility profiles such that each exhibit an at least 1, 2, 3, 4, 5, 6, 7, or 8 weight percent solubility in a solvent used to form the active layer.
